(19) United States
(12) Patent Application Publication
(10) Pub. No.: US 2021/0090923 A1
(43) Pub. Date: Mar. 25, 2021

(54) EFEM AND EFEM SYSTEM

(71) Applicant: Bum Je WOO, Seongnam (KR)

(72) Inventors: Bum Je WOO, Seongnam (KR); Young Chul KIM, Yongin (KR); Jang HEO, Hwaseong (KR)

(21) Appl. No.: 16/630,388

(22) PCT Filed: Jul. 9, 2018
(86) PCT No.: PCT/KR2018/007743

§ 371 Date: Jan. 10, 2020

(30) Foreign Application Priority Data
Jul. 10, 2017 (KR) 10-2017-0087340
Jul. 10, 2017 (KR) 10-2017-0087343

(51) Int. Cl. H01L 21/673; H01L 21/67; H01L 21/677

(52) U.S. Cl. CPC H01L 21/67389; H01L 21/67017; H01L 21/67763; H01L 21/67739; H01L 21/67098

(57) ABSTRACT

The present invention relates to an EFEM for transferring a wafer between a wafer storage container and process equipment and, specifically, to an EFEM which can reduce the defect rate of wafers received in a wafer storage container by actively using a downflow flowing along a wall surface of the EFEM. The present invention relates to an EFEM system for transferring a wafer between a wafer storage container and process equipment and, specifically, to an EFEM system which can selectively achieve moisture removal from wafers and fume removal from wafers depending on conditions of the wafers by controlling the direction of a downflow in a wafer transfer chamber in accordance with environmental conditions inside a wafer storage container.

### CROSS-REFERENCE TO RELATED APPLICATION

This application is a national stage application, filed under 35 U.S.C. § 371, of International Patent Application No. PCT/KR2018/007743, filed on Jul. 9, 2018, which claims the priority of Korean application No. 10-2017-0087343 filed on Jul. 10, 2017 and Korean application No. 10-2017-0087340 filed on Jul. 10, 2017, the contents of which are incorporated by reference.

### TECHNICAL FIELD

The present invention relates to an EFEM configured to perform wafer transfer between a wafer storage container and process equipment, and to an EFEM system.

### BACKGROUND ART

In a semiconductor manufacturing process, wafers are processed in a clean room in order to improve yield and quality. However, as devices have become more highly integrated, circuits have become finer, and wafers have become larger, maintaining cleanness in the entire clean room has become difficult from both a technical and cost point of view.

Therefore, in recent years, the cleanliness only in a local space around wafers has been managed. For this purpose, a module called equipment front end module (EFEM) has been used for storing wafers in a wafer storage container called a front-opening unified pod (FOUP), and performing wafer transfer between the FOUP and process equipment that processes the wafers.

Such an EFEM is configured such that a wafer transfer chamber provided with a wafer transfer device is provided, and a load port to which the FOUP is coupled is connected to a first surface of the wafer transfer chamber, and the process equipment is connected to a second surface of the wafer transfer chamber.

Accordingly, the wafer transfer device transfers wafers stored in the FOUP to the process equipment and transfers the wafers having been processed in the process equipment into the wafer storage container.

The wafer storage container is combined with a device for supplying nitrogen such as a load port to inject/fill nitrogen into the wafer storage container, thereby managing the cleanliness of the wafers stored in the wafer storage container. Also, in a wafer transfer chamber of the EFEM, nitrogen is injected through a downflow, thereby managing the cleanliness of the wafers even during the course of transferring the wafers.

As above, when the wafer storage container injects nitrogen through purge gas stream while the EFEM also injects nitrogen through a downflow, the downflow in the transfer chamber of the EFEM flows downwardly along a wall surface to which the wafer storage container is connected and then flow into an opening of the wafer storage container.

In this case, turbulence is formed at the point where the downflow in the EFEM meets the purge gas stream injected from the wafer storage container. Due thereto, moisture removal from the wafers stored in the wafer storage container may not be performed properly, resulting in a problem that defect rate may increase.

Therefore, the downflow flowing along the wall surface of the EFEM have been considered as a negative factor in view of moisture removal from the wafers.

Development regarding an EFEM to solve the above problem has been made, and an example of this EFEM disclosed in Japanese Patent Application Publication No. 2015-204344 (hereinafter referred to as “Patent Document 1”).

As illustrated in FIG. 1, in an EPMP system of Patent Document 1, wafers are accommodated in a main body 2 of a pod 1, and an inert gas is injected into an accommodation space of the main body 2 through a pod-side nozzle to generate a flow B. The pod 1 has an opening 2a connected to an opening 111 of a side plate such that the pod 1 communicates with a micro-space, and a downflow A of the inert gas generated by a downflow generating mechanism 109 is generated in the micro-space.

In addition, an upper awning 115 that partially obstructs a path of the downflow A is disposed at the side plate, thereby preventing the flow B of the inert gas injected from the pod 1 and the downflow A from meeting each other.

However, in the EFEM system of Patent Document 1, although the upper awning 115 may allow the flow of the downflow A to flow to the opposite side of the pod 1, this is simply to passively change the path of the downflow A. Therefore, turbulence may occur at a portion where the downflow A has flowed, and thus, there is a problem in that the downflow A itself may not flow smoothly.

In other words, provision of the upper awning 115 to block the downflow A from flowing into the main body 2 of the pod 1 may rather obstruct the flow of the downflow A itself.

As above, if the flow of the downflow A is not made smoothly, the downflow A may be concentrated to one side and eventually flow into the main body 2, and thus, there is a problem in that “prevention of the flow of the downflow A into the body 2 of the pod 1” that is believed to be achieved by the upper awning 115 may be failed.

In addition to preventing the flow of the downflow, such as the upper awning of Patent Document 1 described above, there has been developed an EFEM in which an upper awning generates a new downflow. An example of this EFPM disclosed in Korean Patent Application Publication No. 10-2015-009421 (hereinafter referred to as “Patent Document 2”).

In an EFEM of Patent Document 2, nitrogen is injected into an inner space of a purge target container by a bottom purge device of a load port, and a shield curtain device is provided at a position above an upper edge of an opening of the purge target container. Therefore, the shield curtain device jets a shield curtain gas downwardly to form a gas curtain that shields the opening.

However, in the case of the EFEM of Patent Document 2, since the gas curtain formed by the shield curtain device also forms a kind of downflow, when the gas curtain meets nitrogen injected from the bottom purge device, there is a possibility that turbulence may occur in the vicinity of the opening, and thus, there is a problem in that moisture removal from the wafers may not be performed properly.

As described above, in the related art technologies, a member to block a downflow that is generated by a downflow generator such as fan filter unit (FFU) and flows along the wall surface of the EFEM is installed. This is to consider the downflow flowing along the wall surface of the EFEM as a negative factor, and to solve the above-problems on this premise.

Meanwhile, in a semiconductor manufacturing process, wafers are processed in a clean room in order to improve yield and quality. However, as devices have become more highly integrated, circuits have become finer, and wafers have become larger, maintaining cleanness in the entire clean room has become difficult from both a technical and cost point of view.

Therefore, in recent years, the cleanliness only in a local space around wafers has been managed. For this purpose, a module called equipment front end module (EFEM) has been used for storing wafers in a wafer storage container called a front-opening unified pod (FOUP), and performing wafer transfer between the FOUP and process equipment that processes the wafers.

Such an EFEM is configured such that a wafer transfer chamber provided with a wafer transfer device is provided, and a load port to which the FOUP is coupled is connected to a first surface of the wafer transfer chamber, and the process equipment is connected to a second surface of the wafer transfer chamber.

Accordingly, the wafer transfer device transfers wafers stored in the FOUP to the process equipment and transfers the wafers having been processed in the process equipment into the wafer storage container.

As above, the EFEM and the wafer storage container connected to the EFEM constitutes an EFEM system, and in order to reduce the defect rate of large-scale wafers, there has been a need for managing not only the cleanliness of the wafers stored in the wafer storage container but also the cleanliness of the wafers transferred from the wafer transfer chamber.

Accordingly, there has been developed an EFEM system to achieve moisture removal or fume removal from the wafers by injecting/delivering an inert gas such as nitrogen into the wafer storage container and the wafer transfer chamber. Examples of such an EFEM system disclosed in Japanese Patent Application Publication No. 2015-204344 (hereinafter referred to as “Patent Document 1”) and Korean Patent Application Publication No. 10-2015-009421 (hereinafter referred to as “Patent Document 2”).

In an EPMP system of Patent Document 1, wafers are accommodated in a main body of a pod, and an inert gas is injected into an accommodation space of the main body through a pod-side nozzle to generate a flow. The pod has an opening connected to an opening of a side plate such that the pod communicates with a micro-space, and a downflow of the inert gas generated by a downflow generating mechanism is generated in the micro-space.

In addition, an upper awning that partially obstructs a path of the downflow is disposed at the side plate, thereby preventing the flow of the inert gas injected from the pod 1 and the downflow A from meeting each other. This therefore achieves moisture removal from the wafers accommodated in the pod.

However, in the case of Patent Document 1, while moisture removal from the wafers can be achieved by the upper awning that blocks the downflow from flowing into the pod, there is a problem in that fume removal from the wafers may not be properly achieved.

In detail, it is necessary to remove fumes on the wafers by injecting an inert gas and exhausting the inert gas together with the fumes on the wafers. However, in the case of Patent Document 1, the inert gas injected from the pod may not be properly exhausted, and thus the fumes on the wafers in the pod may remain with the inert gas.

Therefore, when the wafers undergo a process in which a lot of fumes are generated, there is a problem in that the wafers may become defective due to the fumes even if moisture of the wafers is removed.

In an EFEM of Patent Document 2, nitrogen is injected into and exhausted from an inner space of a purge target container by a bottom purge device of a load port, and clean air flows downwardly by an FFU to a wafer transfer chamber.

In addition, a shield curtain device is provided at a position above an upper edge of an opening of the purge target container. The shield curtain device jets a shield curtain gas downwardly to form a gas curtain that shields the opening.

Therefore, the cleanliness of wafers stored in the purge target container is managed by nitrogen injected by the bottom purge device, and the cleanliness of wafers transferred to the wafer transfer chamber by a wafer transfer robot is managed by the clean air flowing by the FFU.

However, in the case of Patent Document 2, since managing the cleanliness of the purge target container and the cleanliness of the wafer transfer chamber is individually performed, there is a problem in that waste of nitrogen or clean air may occur.

In addition, in the related art, the downflow is sent uniformly without considering environmental conditions inside the wafer transfer chamber of the EFEM, and thus there is a problem in that a non-uniform air flow may be generated inside the wafer transfer chamber.

### DOCUMENTS OF RELATED ART

### Patent Documents

(Patent document 1) Japanese Patent Application Publication No. 2015-204344
(Patent document 2) Korean Patent Application Publication No. 10-2015-009421

### DISCLOSURE

### Technical Problem

Accordingly, the present invention has been made keeping in mind the above problems occurring in the related art, and an objective of the present invention is to provide an EFEM which can reduce the defect rate of wafers stored in a wafer storage container by actively using a downflow flowing along a wall surface of the EFEM.

Another objective of the present invention is to provide an EFEM system which can selectively achieve moisture removal from wafers and fume removal from the wafers in accordance with conditions of the wafers by controlling the direction of a downflow in a wafer transfer chamber in accordance with environmental conditions inside a wafer storage container.

Still another objective of the present invention is to provide an EFEM system which can achieve a uniform flow of downflow by controlling the downflow in a wafer transfer chamber in accordance with environmental conditions inside the wafer transfer chamber of an EFEM.

### Technical Solution

According to one aspect of the present invention, there is provided an EFEM that is configured such that a wafer storage container is connected to an opening formed in a wall surface of the EFEM and a wafer transfer chamber is provided therein, the EFEM including: a gas delivery part provided in an upper portion of the wafer transfer chamber and delivering gas into the wafer transfer chamber; a gas suction part provided in a lower portion of the wafer transfer chamber and suctioning the gas inside the wafer transfer chamber; and an airflow control wing provided between the gas delivery part and the gas suction part, installed to be spaced apart from the wall surface, and controlling a downflow flowing to a space defined between the airflow control wing and the wall surface.

Furthermore, an element of the downflow controlled by the airflow control wing may be a flow velocity or direction.

Furthermore, the airflow control wing may have a curvature.

Furthermore, the airflow control wing may include a first convex portion formed convexly in a direction of the wall surface.

Furthermore, the airflow control wing may include a second convex portion formed convexly in a direction opposite to the wall surface.

Furthermore, a length of the airflow control wing in a spanwise direction may be equal to or greater than a horizontal length of the opening.

Furthermore, the airflow control wing may include a leading edge striking the downflow, a first side surface extending from the leading edge to have a curvature convex in a direction of the wall surface, a second side surface extending from the leading edge to have a curvature convex in a direction opposite to the wall surface, and a trailing edge extending from the first and second side surfaces and located opposite to the leading edge.

Furthermore, a trailing edge of the airflow control wing may be inclined toward the wall surface.

Furthermore, the airflow control wing may be tiltable.

Furthermore, the airflow control wing may be provided as a plurality of airflow control wings.

Furthermore, the plurality of airflow control wings may be installed to have a height difference.

Furthermore, the suction part may be comprised of a plurality of suction parts that can perform individual suction, and the plurality of suction parts may be configured to control a direction of the downflow separated from the airflow control wing.

Furthermore, the airflow control wing may further include: a heater provided at the airflow control wing.

Furthermore, the airflow control wing may include: a gas spraying part provided at the airflow control wing.

Furthermore, a plurality of protrusions may be formed on the wall surface.

Furthermore, a plurality of dimples may be formed on the wall surface.

According to another aspect of the present invention, there is provided an EFEM system including a wafer transfer chamber, wherein the EFEM system controls a downflow of the wafer transfer chamber in accordance with environmental conditions inside the wafer transfer chamber.

According to still another aspect of the present invention, there is provided an EFEM system including a wafer storage container in which wafers are stored and an EFEM including a wafer transfer chamber to which the wafer storage container is connected, the EFEM system including: a controller allowing the downflow in the wafer transfer chamber to flow in a direction of inside of the wafer storage container or to flow in a direction opposite to the wafer storage container in accordance with the environmental conditions inside the wafer storage container.

The EFEM system may further include: a concentration sensor measuring a concentration of noxious gas inside the wafer storage container; and a first exhaust part provided inside the wafer storage container, wherein when a value measured by the concentration sensor is greater than a preset concentration limit value, the controller may operate the first exhaust part to allow the downflow in the direction of the inside of the wafer storage container.

The EFEM system may further include: a humidity sensor measuring a humidity inside the wafer storage container; and a second exhaust part provided in the wafer transfer chamber, wherein when a value measured by the humidity sensor is greater than a preset humidity limit value, the controller may operate the second exhaust part to allow the downflow in the direction opposite to the wafer storage container.

The EFEM system may further include: a concentration sensor measuring a concentration of noxious gas inside the wafer storage container; and an airflow control device provided in the wafer transfer chamber and controlling a direction of the downflow in accordance with a change in angle, wherein when a value measured by the concentration sensor is greater than a preset concentration limit value, the controller may control the angle of the airflow control device to a first direction angle such that the downflow may flow in the direction of the inside of the wafer storage container.

The EFEM system may further include: a flow sensor measuring a flow rate of the downflow flowing in the direction of the inside of the wafer storage container; an airflow control device heater provided at the airflow control device to increase a temperature inside the wafer transfer chamber during operation; and a gas spraying part provided at the airflow control device to spray gas during operation, wherein when the downflow flows in the direction of the inside of the wafer storage container by the airflow control device and a value measured by the flow sensor is less than a flow rate limit value preset in the controller, the controller may operate at least one of the airflow control device heater or the gas spraying part.

The EFEM system may further include: a humidity sensor measuring a humidity inside the wafer storage container; and an airflow control device provided in the wafer transfer chamber and controlling a direction of the downflow in accordance with a change in angle, wherein when a value measured by the humidity sensor is greater than a preset humidity limit value, the controller may control the angle of the airflow control device to a second direction angle such that the downflow may flow in the direction opposite to the wafer storage container.

The EFEM system may further include: a temperature sensor measuring a temperature inside the wafer storage container; and a heater provided at the wafer storage container to increase a temperature inside the wafer storage container during operation, wherein when the downflow flows in the direction opposite to the wafer storage container by the airflow control device and a value measured by the temperature sensor is less than a preset temperature limit value, the controller may operate the heater.

### Advantageous Effects

The EFEM according to the present invention as described above has the following effects.

The airflow control wing controls the downflow to not flow into the wafer storage container, and thus the injection flow in the wafer storage container and the downflow in the wafer transfer chamber do not meet each other. Therefore, it is possible to prevent the occurrence of turbulence in the vicinity of the opening of the wall surface, whereby the injection flow can easily flow to the direction in front of the wafers to remove moisture from the wafers more effectively.

While the airflow control wing controls the downflow, the plurality of suction parts individually suctions the controlled downflow, thereby making it possible to more effectively control the downflow.

The plurality of protrusions or the plurality of dimples are formed on the surface of the wall surface, thereby making it possible to reduce surface friction drag of the downflow flowing along the wall surface and thus to achieve a smooth flow of the downflow and of the laminar flow generated by the airflow control wing.

The EFEM system according to the present invention as described above has the following effects.

The downflow in the wafer transfer chamber is controlled in accordance with environmental conditions inside the wafer transfer chamber, thereby making it possible to achieve a uniform flow of downflow in the wafer transfer chamber.

The downflow in the EFEM is flowed in the direction of the wafer storage container or in the direction opposite to the wafer storage container in accordance with environmental conditions inside the wafer storage container, thereby making it possible to selectively achieve fume removal or moisture removal from the wafers stored in the wafer storage container as needed.

During the fume removal operation for removing fumes on the wafers, the fumes on the wafers are removed by the use of both the injection flow in the wafer storage container and the downflow in the EFEM, thereby making it possible to save the time of fume removal while preventing the waste of gas.

When the fume removal operation for removing fumes on the wafers is performed by controlling the direction of the downflow through the airflow control device, the downflow is converted into the laminar flow and flows into the wafer storage container, thereby making it possible to achieve more effective fume removal from the wafers.

It is possible to increase the flow rate of the downflow flowing into the wafer storage container by the use of the airflow control device heater or gas spraying part of the airflow control device, thus achieving quicker fume removal from the wafers.

During the moisture removal operation for removing moisture in the wafers, it is possible to prevent possible dead zones of the wafers, in which gas fails to be injected, by preventing the injection flow in the wafer storage container and the downflow in the EFEM from not meeting each other in the vicinity of the front opening of the wafer storage container (or in the vicinity of the opening), thereby achieving effective moisture removal from the wafers.

When performing the moisture removal operation for removing moisture in the wafers by controlling the direction of the downflow by the use of the airflow control device, the downflow is converted into the laminar flow and flows into the wafer storage container, thereby making it possible to achieve more effective moisture removal from the wafers.

### DESCRIPTION OF DRAWINGS

FIG. 1 is a view illustrating an EFEM in the related art.

FIG. 2 is a view illustrating an EFEM according to a preferred embodiment of the present invention.

FIGS. 3a and 3b are views illustrating an airflow control wing of FIG. 2.

FIGS. 4a, 4b, and 4c are views illustrating a flow change of a downflow due to the airflow control wing of FIGS. 3a and 3b.

FIG. 5 is a view illustrating flow of the downflow of FIG. 2.

FIG. 6 is a view illustrating an EFEM system according to a first preferred embodiment of the present invention.

FIG. 7 is a view illustrating a connection between a controller, measurement elements, and control elements of the EFEM system according to the first preferred embodiment of the present invention.

FIG. 8 is a view illustrating that the downflow in a wafer transfer chamber of FIG. 6 flows into a wafer storage container and is exhausted to a first exhaust part.

FIG. 9 is a view illustrating that jet stream in the wafer storage container and the downflow in the wafer transfer chamber flow to a wafer in the state of FIG. 8.

FIG. 10 is a view illustrating that the downflow in the wafer transfer chamber of FIG. 6 flows in a direction opposite to the wafer storage container and is exhausted to a second exhaust part.

FIG. 11 is a view illustrating an EFEM system according to a second preferred embodiment of the present invention.

FIGS. 12a and 12b are views illustrating an airflow control device of FIG. 11.

FIG. 13 is a view illustrating a connection between a controller, measurement elements, and control elements of the EFEM system according to the second preferred embodiment of the present invention.

FIG. 14 is a view illustrating that a downflow in a wafer transfer chamber of FIG. 11 flows into a wafer storage container and is exhausted to a first exhaust part.

FIG. 15 is a view illustrating a flow change of the downflow due to the airflow control device in the state of FIG. 14.

FIG. 16 is a view illustrating that the downflow in the wafer transfer chamber of FIG. 11 flows in a direction opposite to the wafer storage container and is exhausted to a second exhaust part.

FIG. 17 is a view illustrating a flow change of the downflow due to the airflow control device in the state of FIG. 16.

### MODE FOR INVENTION

The term “gas” referred to below is a general term for an inert gas for removing fumes or moisture from a wafer, and in particular, may be nitrogen (N₂) gas, which is one of inert gases.

A downflow D in a wafer transfer chamber 150 and an injection flow I in a wafer storage container 50 refer to airflows formed by the above-described gas.

In addition, the downflow D which flows to a space defined between a wall surface 151 and an airflow control wing 200 spaced apart from each other under control of the airflow control wing 200 includes a first convex portion flow D1, a second convex portion flow D2, and a laminar flow L.

Hereinafter, an EFEM according to a preferred embodiment of the present invention will be described with reference to the accompanying drawings.

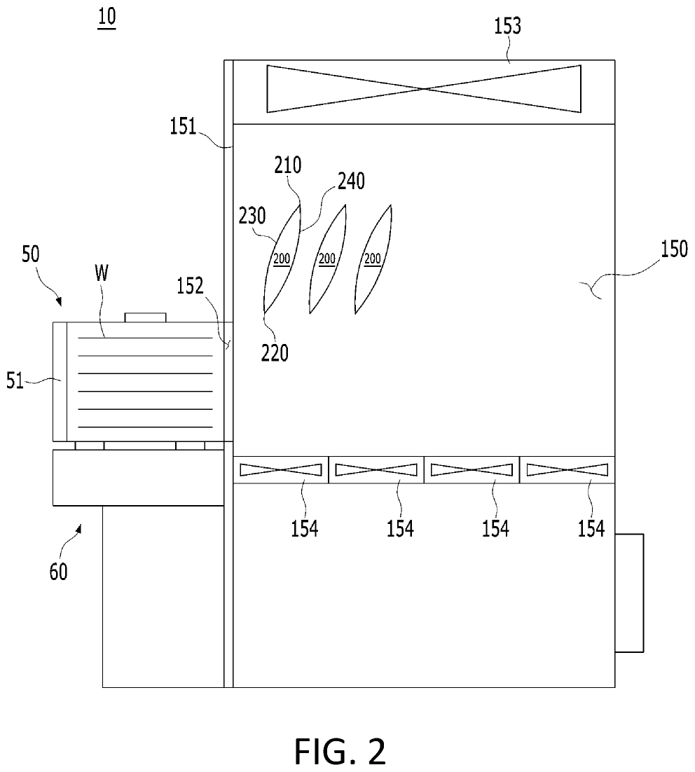

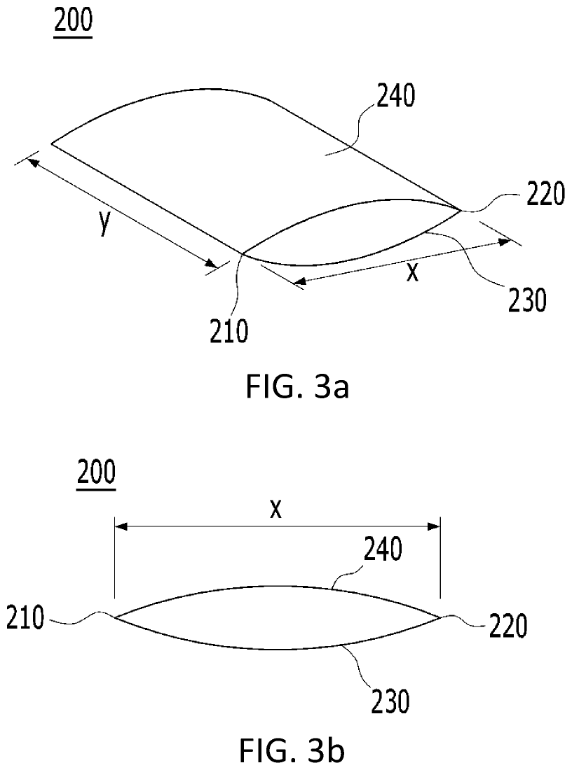

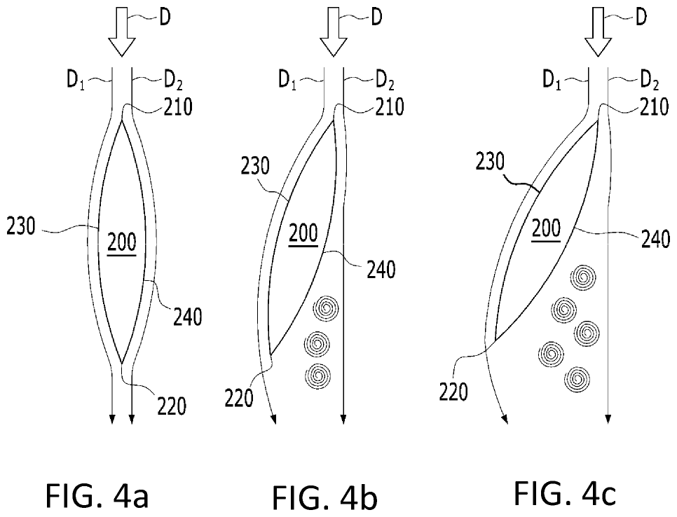

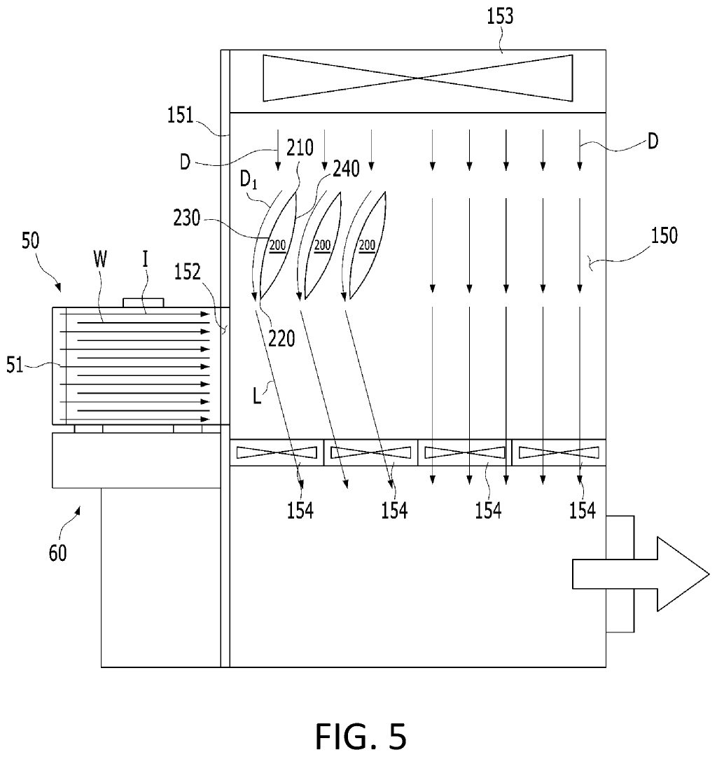

FIG. 2 is a view illustrating an EFEM according to a preferred embodiment of the present invention, FIGS. 3a and 3b are views illustrating an airflow control wing of FIG. 2, FIG. 4 is a view illustrating a flow change of a downflow due to the airflow control wing of FIGS. 3a and 3b, and FIG. 5 is a view illustrating flow of the downflow of FIG. 2.

As illustrated in FIG. 2, an equipment front end module (EFEM) 10 according to a preferred embodiment of the present invention includes a wafer transfer chamber 150 including a wall surface 151 to which a wafer storage container 50 is connected, a gas delivery part 153 provided in an upper portion of the wafer transfer chamber 150 to deliver gas into the wafer transfer chamber 150, a gas suction part 154 provided in a lower portion of the wafer transfer chamber 150 to suction the gas inside the wafer transfer chamber 150, and an airflow control wing 200 provided between the gas delivery part 153 and the gas suction part 154, installed to be spaced apart from the wall surface 151, and controlling a downflow D flowing to a space defined between the airflow control wing and the wall surface 151.

The wafer storage container 50 has wafers W stored therein, with a front opening (not illustrated) formed at a front side thereof and through which the wafers W enter and exit.

The wafer storage container 50 not only functions as a storage container for storing the wafers W, but also functions to inject gas toward the wafers W through an injection part 51 provided in the wafer storage container 50 to remove moisture or fumes.

The wafer storage container 50 is placed on top of a loading device 60, and thus, the front opening of the wafer storage container 50 is easily connected to an opening 152 of the wall surface 151 of the wafer transfer chamber 150 of the EFEM 10.

In this case, the loading device 60 collectively refers to a device for loading the wafer storage container 50, such as a load port. In the loading device 60, a loading device injection part (not illustrated) and a loading device exhaust part (not illustrated) are provided to communicate with the injection part 51 and an exhaust part (not illustrated) of the wafer storage container 50, respectively.

The loading device injection part is in communication with an external gas supply part (not illustrated), and thus, externally supplied gas is injected into the wafer storage container 50 through the external gas supply part, the loading device injection part of the loading device 60, and the injection part 51 of the wafer storage container 50 and thus can be easily injected toward the wafers W stored in the wafer storage container 50.

The gas injected toward the wafers W stored in the wafer storage container 50, i.e., the gas injected into the wafer storage container 50 forms the injection flow I as illustrated in FIG. 5.

The loading device exhaust part is in communication with the external gas exhaust part (not illustrated), and thus, the gas injected into the wafer storage container 50 and fumes on the wafers W are exhausted from inside the wafer storage container 50 to the loading device 60 and the external gas exhaust part through the exhaust part of the wafer storage container 50 and the loading device exhaust part and the external gas exhaust part of the loading device 60, and thus the fumes on the wafers W stored in the wafer storage container 50 can be easily removed.

In addition, a wafer storage container heater (not illustrated) may be provided at the wafer storage container 50. The wafer storage container heater functions to increase the temperature inside the wafer storage container 50 to remove moisture from the wafers W.

The wafer storage container 50 described above may be a mobile type in which the wafer storage container 50 itself is moved by an automation system or a user and placed on the loading device 60, or may be a stationary type in which the wafer storage container 50 is placed on the loading device 60 while being coupled to the loading device 60 without being moved.

The wafer transfer chamber 150 refers to a space in which the wafers W are transferred in the EFEM 10by a wafer transfer device (not illustrated) such as a robot arm.

The wall surface 151 is provided at one side of the wafer transfer chamber 150, and the opening 152 is formed in the wall surface 151.

The opening 152 of the wall surface 151 at one side of the wafer transfer chamber 150 communicates with the front opening of the wafer storage container 50, whereby the wafer storage container 50 is connected to one side of the wafer transfer chamber 150.

In addition, process equipment (not illustrated) which performs a process, such as an etching, to the wafers W is connected to the other side of the wafer transfer chamber 150.

Therefore, the wafer transfer device may transfer the wafers W stored in the wafer storage container 50 to the process equipment to perform the process, or may transfer the wafers W having undergone the process in the process equipment to the wafer storage container 50. This transfer (or retransfer) of the wafers W is performed in the wafer transfer chamber 150.

A plurality of protrusions (not illustrated) may be formed on the surface of the wall surface 151. In this case, it is preferable that each of the plurality of protrusions is formed as a triangular protrusion, such as a riblet. The protrusions serve to reduce skin friction drag on the wall surface 151. Therefore, friction drag of the downflow D flowing along the wall surface 151 is reduced by the plurality of protrusions, and, due thereto, flow velocity of the downflow D can be increased.

In addition, a plurality of dimples (not illustrated) may be formed on the surface of the wall surface 151. The plurality of dimples also serves to reduce the skin friction drag on the wall surface 151 to increase the flow velocity of the downflow D, similar to the plurality of protrusions described above.

Airflow of which the flow velocity is increased by the plurality of protrusions or the plurality of dimples described above includes not only the downflow D but also the first convex portion flow D1 generated by the airflow control wing 200 which will be described later.

In other words, the plurality of protrusions or the plurality of dimples function to not only facilitate the flow of the downflow D by increasing the flow velocity of the downflow D flowing along the wall surface 151, but also facilitate the flow of the laminar flow L generated by the first convex portion flow D1 by increasing the flow velocity of the downflow D flowing along the space defined between the airflow control wing 200 and the wall surface 151, i.e., airflow including the first air convex flow D1.

The gas delivery part 153 is provided in the upper portion of the wafer transfer chamber 150 and functions to deliver the gas into the wafer transfer chamber 150.

In this case, the gas delivery part 153 may be a fan filter unit (FFU) including a delivery fan for delivering gas and a filter for filtering and cleaning the gas.

The gas suction part 154 is provided in the lower portion of the wafer transfer chamber 150 and functions to suction the gas in the wafer transfer chamber 150.

As above, since the gas delivery part 153 and the gas suction part 154 are provided in the upper and lower portions of the wafer transfer chamber 150, the gas delivered from the gas delivery part 153 may be suctioned into the gas suction part 154, whereby the downflow D may be formed in the wafer transfer chamber 150.

The gas suction part 154 may be comprised of a plurality of gas suction parts 154. In this case, each of the plurality of gas suction parts 154 may be configured such that a suction fan or the like for generating a suction force is provided, and the respective suction fans or the like are operated individually to enable individual suction.

Hereinafter, the airflow control wing 200 will be described.

FIG. 3a is a perspective view illustrating the airflow control wing 200 of FIG. 2, and FIG. 3b is a sectional view of the airflow control wing 200 of FIG. 2.

However, for ease of explanation, in the following description, the “x” direction (the direction from a leading edge 210 to a trailing edge 220) illustrated in FIGS. 3a and 3b is referred to as a chordwise direction of the airflow control wing 200, and the “y” direction illustrated in FIG. 3a is referred to as a spanwise direction.

As illustrated in FIG. 2, the airflow control wing 200 is installed to be spaced apart from the wall surface 151 and functions to control the downflow D flowing to the space defined between the airflow control wing 200 and the wall surface 151.

In addition, as illustrated in FIGS. 3a and 3b, the airflow control wing 200 includes the leading edge 210 striking the downflow D, a first convex portion 230 extending from the leading edge 210 to have a convex curvature in the direction of the wall surface 151, a second convex portion 240 extending from the leading edge 210 to have a curvature convex in the direction opposite to the wall surface 151, and the trailing edge 220 extending from the first convex portion 230 and the second convex portion 240 and located opposite to the leading edge 210.

The leading edge 210 is formed at a front side of the airflow control wing 200 and is a portion where the downflow D strikes directly when the downflow D is generated.

The trailing edge 220 is formed at a rear side of the airflow control wing 200 and is a portion where the downflow D does not strike directly since the trailing edge 220 is located opposite to the leading edge 210.

The first convex portion 230 is formed on a first side surface of the airflow control wing 200 to have a convex curvature in the direction of the wall surface 151, while the second convex portion 240 is formed on a second side surface of the airflow control wing 200 to have a convex curvature in the direction opposite to the wall surface 151.

In this case, the opposite side of the first side surface is the second side surface. Therefore, the second convex portion 240 is formed on the opposite side of the first convex portion 230.

The first convex portion 230 and the second convex portion 240 extend from the leading edge 210 to meet at the trailing edge 220. In other words, the leading edge 210, the first and second convex portions 230 and 240, and the trailing edge 220 form a continuous surface. As a result, as illustrated in FIG. 3b, a cross section of the airflow control wing 200, i.e., an airfoil is formed.

The airflow control wing 200 may include a heater (not illustrated). The heater functions to increase the temperature inside the wafer transfer chamber 150 by heating the airflow control wing 200 to heat the downflow D in contact with the airflow control wing 200.

When the downflow D is heated by the heater of the airflow control wing 200, the downflow D is further activated. This therefore provides an effect of increasing the flow velocity of the downflow D (because gas is activated when heated and the velocity thereof increases).

It is preferable that the heater is provided inside the airflow control wing 200.

The airflow control wing 200 may include a gas spraying part (not illustrated). The gas spraying part is provided on the surface of the airflow control wing to spray gas, thereby functioning to supply an additional gas flow rate and simultaneously to allow gas flowing along the surface of the airflow control wing 200, i.e., the downflow D to flow at a higher velocity.

It is preferable that the gas spraying part is provided on the surface of the airflow control wing, i.e., on at least one of the first convex portion 230 and the second convex portion 240. The gas spraying part may be provided on at least one of the first convex portion 230 and the second convex portion 240 in a form of a nozzle.

The airflow control wing 200 having the above configuration is installed to be spaced apart from the wall surface 151 of the wafer transfer chamber 150.

In this case, in the airflow control wing 200, it is preferable that the lowest portion (the trailing edge 220 in FIG. 2) of the airflow control wing 200 is located above the front opening of the wafer storage container 50 and the opening 152 of the wall surface 151.

This is to prevent the airflow control wing 200 from interfering with transfer of the wafer transfer device when the wafer transfer device transfers the wafers W.

In the airflow control wing 200, it is preferable that the length of the airflow control wing 200 in the spanwise direction (the length in the y direction illustrated in FIG. 3a) is equal to or greater than the horizontal length of the opening 152 of the wall surface 151.

This because when the length of the airflow control wing 200 in the spanwise direction is less than the horizontal length of the opening 152 of the wall surface 151, i.e., when the length of the airflow control wing 200 in the spanwise direction is smaller than the horizontal length of the opening 152 of the wall surface 151, the downflow D flows by being bent on the left and right sides of the airflow control wing 200 and thus it is not easy to control the direction of the downflow D, such as flowing in the direction of the inside of the wafer storage container 50, or flowing in the direction opposite to the wafer storage container 50.

The airflow control wing 200 may be installed to be tiltable. Tilting of the airflow control wing 200 is performed by a driving part (not illustrated). Therefore, as illustrated in FIGS. 4a, 4b, and 4c, the angle of attack of the airflow control wing 200 may vary according to driving of the driving part (detailed description of the angle of attack will be described later).

The airflow control wing 200 may be provided as a plurality of airflow control wings. The plurality of airflow control wings 200 may be installed to have a height difference.

The height difference of the plurality of airflow control wings 200 refers that the heights of trailing edges 220 of the plurality of airflow control wings 200 are positioned differently from each other upon installation.

In this case, the plurality of airflow control wings 200 may be installed such that the heights of the trailing edges 220 of the plurality of airflow control wings 200 gradually decrease in the direction of the wall surface 151. On the contrary, the plurality of airflow control wings 200 may be installed such that the heights of the trailing edges 220 of the plurality of airflow control wings 200 gradually decrease in the direction opposite to the wall surface 151.

As such, since the plurality of airflow control wings 200 is installed to have a height difference from each other, it is possible to more easily control the downflow D in a desired direction.

Hereinafter, the control of the downflow D of the EFEM 10 according to the preferred embodiment of the present invention by the use of the airflow control wings 200 will be described with reference to FIGS. 4a-4c and 5.

FIG. 4a is a view illustrating when the angle of attack of each airflow control wing 200 is 0°, FIG. 4a is a view illustrating when the angle of attack of each airflow control wing 200 is 15°, and FIG. 4a is a view illustrating when the angle of attack of each airflow control wing 200 is 25°.

In this case, the angle of attack refers to the angle between the inclination of each airflow control wing 200 and the flow direction of the downflow D.

In addition, the angle of attack illustrated in each of FIGS. 4a to 4c is illustrated showing when the trailing edge 220 of each airflow control wing 200 is inclined toward the wall surface 151, and the airflow control wings illustrated in FIGS. 2 to 5 are illustrated showing when the angle of attack of each airflow control wing 200 is 25° as illustrated in FIG. 4c.

First, as illustrated in FIG. 4c, the flow of the downflow D when the angle of attack of each airflow control wing 200 is 25° will be described.

The downflow D strikes the trailing edge 210 of the airflow control wing 200 and then flows separately to the surfaces of the first convex portion 230 and the second convex portion 240.

In this case, in the case of airflow flowing to the surface of the first convex portion 230 (hereinafter referred to as “first convex portion flow D1”), since the angle of attack of the airflow control wing 200 is formed in the direction of the wall surface 151 and the first convex portion 230 has a convex curvature, a Coanda effect occurs.

When the Coanda effect occurs, the first convex portion flow D1 flows in the direction opposite to the wall surface 151 along the curvature of the first convex portion 230, and the flow velocity thereof further increases.

Therefore, even if the first convex portion flow D1 leaves the trailing edge 220 of the airflow control wing 200, a high flow velocity can be maintained, thereby forming a laminar flow L of high flow velocity.

Meanwhile, in the case of airflow flowing to the surface of the second convex portion 240 (hereinafter referred to as “second convex portion flow D2”), since the angle of attack of the airflow control wing is formed in the direction of the wall surface 151, separation flow occurs. Therefore, the second convex portion flow D2 forms turbulence at a lower portion of the second convex portion 240, and, due thereto, the flow velocity thereof decreases.

In other words, the second convex portion flow D2 is separated from the airflow control wing 200 due to the separation flow and does not form a laminar flow but turbulence unlike the first convex portion flow D1.

This is because the second convex portion flow D2 flowing along the second convex portion 240 is converted from a laminar flow into drag force on the basis of a transition point (or separation point) by the separation flow principle. In this case, the flow velocity at the transition point (or separation point) converges to “0”.

Therefore, a relationship of “flow velocity of the first convex portion flow D1>flow velocity of the downflow D>flow velocity of the second convex portion flow D2” is fulfilled.

Hereinafter, as illustrated in FIG. 4b, the flow of the downflow D when the angle of attack of each airflow control wing 200 is 15° will be described.

Also in the case of FIG. 4b, since the angle of attack is 15°, when the downflow D is separated into the first convex portion flow D1 and the second convex portion flow D2, the Coanda effect occurs in the first convex portion flow D1, and the separation flow occurs in the second convex portion flow D2. However, since the angle of attack is smaller than in the case of FIG. 4c, the separation flow does not occur more than in the case of FIG. 4c, and thus, the laminar flow generation effect of the first convex portion flow D1 due to the Coanda effect is smaller than in the case of FIG. 4c.

In the case of FIG. 4a, since the angle of attack is 0°, the downflow D is separated into the first convex portion flow D1 and the second convex portion flow D2, but the Coanda effect of the first convex portion flow D1 and the separation flow of the second convex portion flow D2 do not occur. Therefore, unlike the above-described FIGS. 4b and 4c, no laminar flow is formed.

As described above, the downflow D by the airflow control wing 200 is controlled as a result of the first convex portion flow D1 where the Coanda effect occurs by the first convex portion 230 and the second convex portion flow D2 where the separation flow occurs by the second convex portion 240.

In addition, in the control of the downflow D, whether the Coanda effect and the separation flow occur varies depending on the angle of attack. In order to maximize this, it is preferable that the angle of attack is 25°.

Of course, the angle of attack may vary to some extent depending on the shape of the first and second convex portions 230 and 240. However, in the case of each of the airflow control wings 200 of the EFEM 10 according to the preferred embodiment of the present invention, it is most preferable that the angle of attack is in a range of 15° to 25°.

As described above, since the downflow D is separated into the first convex portion flow D1 and the second convex portion flow D2 while passing through each of the airflow control wings 200 and the characteristics thereof are changed, as illustrated in FIG. 5, the downflow D flowing to spaces between the airflow control wings 200 and the wall surface 151 consequently forms the laminar flow L that flows in the direction opposite to the wall surface 151.

In other words, due to the airflow control wings 200, the downflow D flowing to the spaces between the wall surface 151 and the airflow control wings 200 is controlled in terms of the flow velocity of the downflow D, or the direction of the downflow D, or the flow velocity and direction of the downflow D (hereinafter referred to as “flow velocity and/or direction of the downflow D”). That is, elements of the downflow D controlled by the airflow control wings 200 are the flow velocity and/or direction of the downflow D.

When the flow velocity and/or direction of the downflow D is controlled as such, the flow rate, pressure, and the like of the downflow D may be also controlled.

As above, through the control of the downflow D by the airflow control wings 200, the downflow D does not flow into the wafer storage container 50, and thus, the injection flow I injected from the injection part 51 of the wafer storage container 50 and the downflow D do not meet each other.

Therefore, unlike a wafer storage container in the related art, the injection flow I injected from the injection part 51 of the wafer storage container 50 and the downflow D do not meet each other, thereby making it possible to prevent turbulence from occurring in the vicinity of the opening 152 of the wall surface 151.

As above, since turbulence does not occur in the vicinity of the opening 152 of the wall surface 151, the injection flow I injected from the injection part 51 can easily flow to in front of the wafers W (to the front opening of the wafer storage container 50 or to the opening 152 of the wall surface 151). This makes it possible to prevent possible dead zones of the wafers W, in which gas fails to flow, and thus to efficiently remove moisture from the wafers W.

In addition, in the case of the second convex portion flow D2 in which the separation flow is occurred by the second convex portion 240, the flow velocity thereof is decreased by turbulence or the like, and thus suction control thereof is very advantageous.

In other words, as described above, when a suction force of a gas suction part 154 located opposite to the wall surface 151 is increased among the plurality of gas suction parts 154, the second convex portion flow D2 can be suctioned smoothly due to a low flow velocity thereof. Due thereto, it is possible to reliably prevent the second convex portion flow D2 from flowing in the direction of the wall surface 151, i.e., in the direction of the wafer storage container 50.

As above, the EFEM 10 according to the preferred embodiment of the present invention can easily control the downflow D that flows along the spaces between the wall surface 151 and the airflow control wings 200 by the use of the airflow control wings 200 provided in the wafer transfer chamber 150.

Therefore, unlike the EFEM in the related art which allows the downflow to flow in the direction opposite to the wafer storage container by simply blocking the downflow, due to the Coanda effect occurring in the first convex portion flow D1 flowing along the surface of the first convex portion 230, the laminar flow L is formed whereby the downflow is controlled to flow in the direction opposite to the wall surface 151 and the flow velocity thereof is increased. Due thereto, it is possible to more reliably prevent the flow of the downflow into the wafer storage container 50.

In addition, since the flow velocity of the second convex portion flow D2 is decreased due to the separation flow occurring in the second convex portion flow D2 flowing to the surface of the second convex part 240, and thus control thereof is very easy. Due thereto, it is possible to maximize the effect of individual control of the plurality of gas suction parts 154, as well as preventing that the flow rate of is concentrated in the direction opposite to the wall surface 151, i.e., in the direction opposite to the wafer storage container 50 and the flow of the downflow D is interfered.

Therefore, even if the downflow D which is controlled by the airflow control wings 200 is controlled in terms of the flow velocity and/or direction thereof, the downflow can be easily delivered and suctioned without fear that the flow thereof in the direction from the gas delivery part 153 to the gas suction parts 154, i.e., the flow in the direction from the upper portion to the lower portion of the wafer transfer chamber 150 will be interfered.

In other words, the second convex portion flow D2 separated by the airflow control wings 200 is easily controlled by the individual suction of the plurality of suction parts 154. Therefore, due to organic combination of the second convex portions 240 of the airflow control wings 200 and the plurality of suction parts 154, there is an effect of facilitating the control of the downflow D.

Although the preferred embodiment of the present invention has been described for illustrative purposes, those skilled in the art will appreciate that various modifications, additions and substitutions are possible, without departing from the scope and spirit of the invention as disclosed in the accompanying claims.

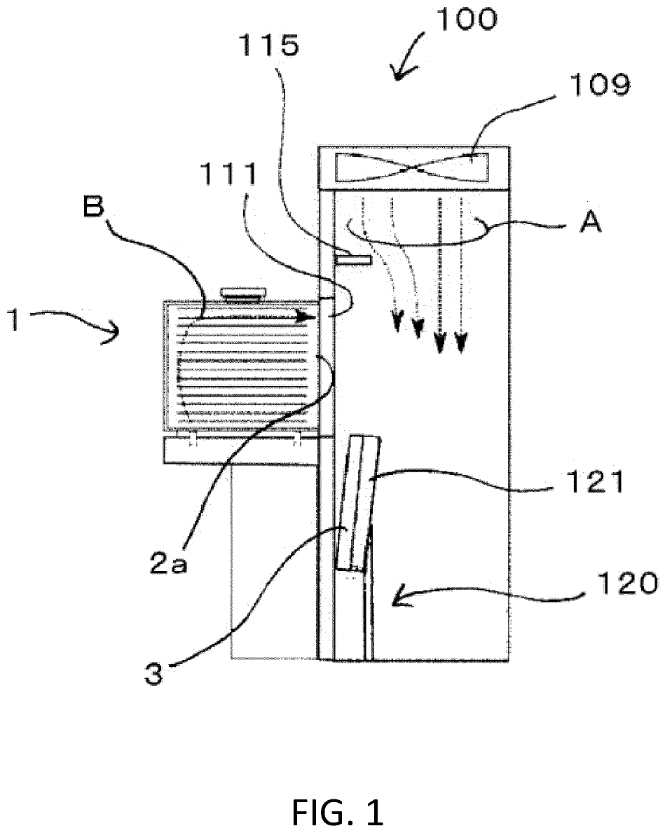

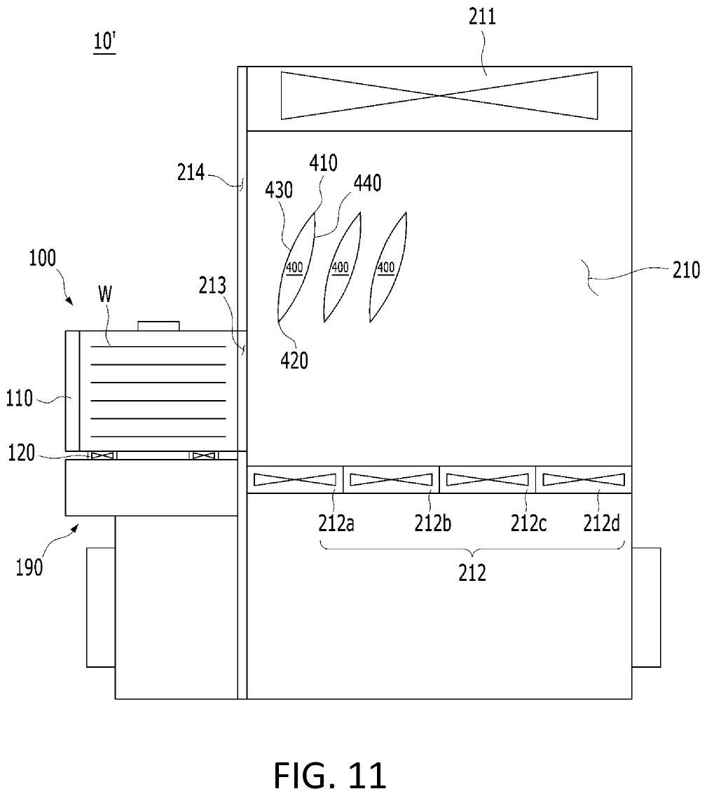

Reference numerals of FIGS. 11 to 17 referred to in the following description may be distinguished from reference numerals of FIGS. 1 to 5 referred to in the foregoing description.

The term “gas” referred to below is a general term for an inert gas for removing fumes or moisture from a wafer, and in particular, may be nitrogen (N₂) gas, which is one of inert gases.

A downflow D in a wafer transfer chamber 210 and an injection flow I in a wafer storage container 100 refer to airflows formed by the above-described gas.

In addition, the downflow D which is controlled by an airflow control device 400 includes a first convex portion flow D1, a second convex portion flow D2, and a laminar flow L.

Hereinafter, an EFEM system according to preferred embodiments of the present invention will be described with reference to the accompanying drawings.

### EFEM System 10 According to a First Preferred Embodiment of the Present Invention

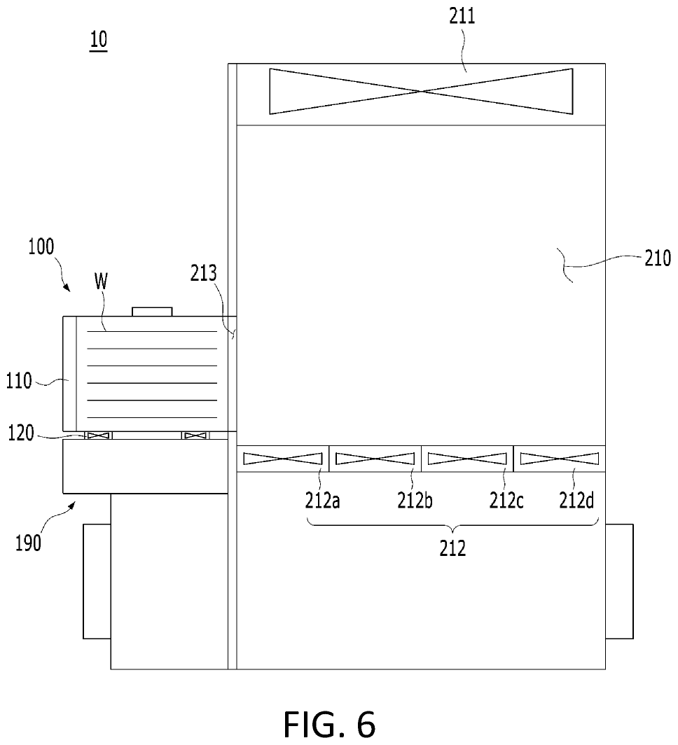

First, an EFEM system 10 according to the first preferred embodiment of the present invention will be described with reference to FIGS. 6 to 10.

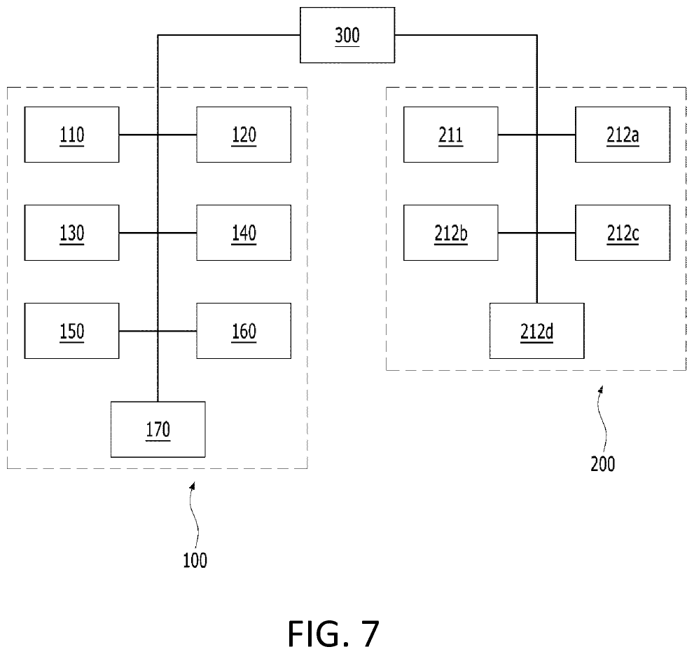

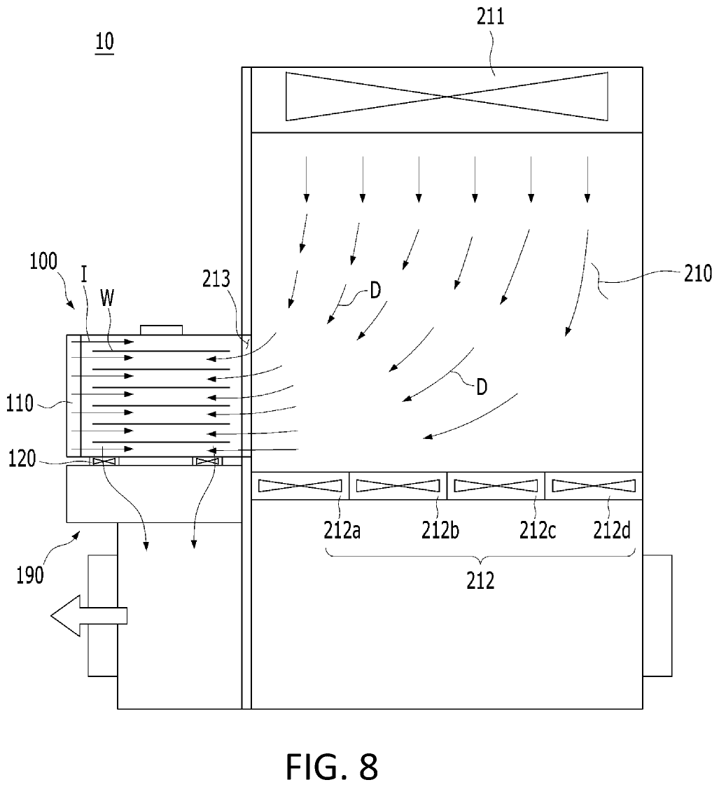

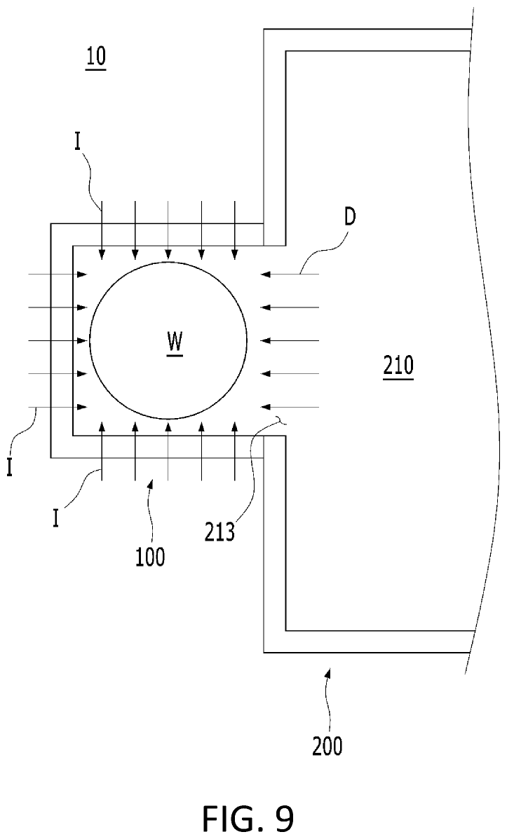

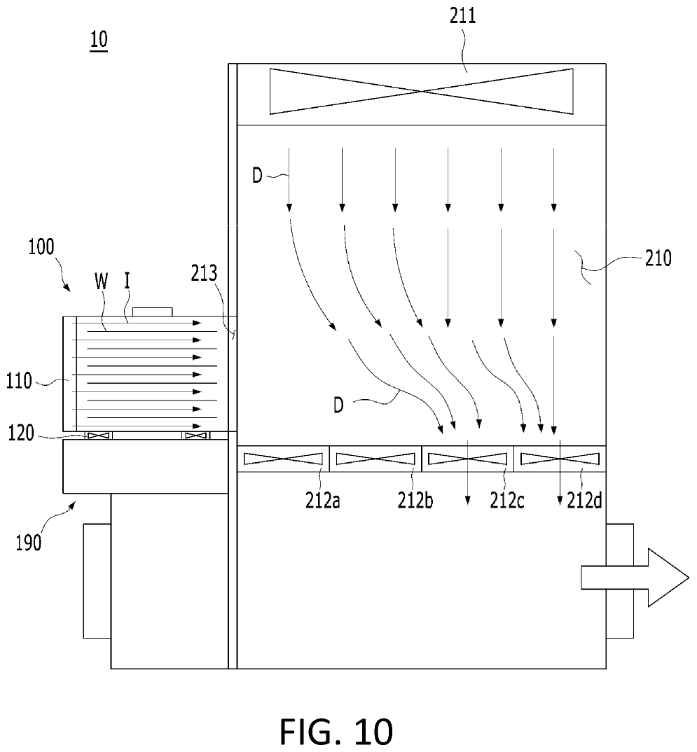

FIG. 6 is a view illustrating an EFEM system according to a first preferred embodiment of the present invention, FIG. 7 is a view illustrating a connection between a controller, measurement elements, and control elements of the EFEM system according to the first preferred embodiment of the present invention, FIG. 8 is a view illustrating that the downflow in a wafer transfer chamber of FIG. 6 flows into a wafer storage container and is exhausted to a first exhaust part, FIG. 9 is a view illustrating that jet stream in the wafer storage container and the downflow in the wafer transfer chamber flow to a wafer in the state of FIG. 8, and FIG. 10 is a view illustrating that the downflow in the wafer transfer chamber of FIG. 6 flows in a direction opposite to the wafer storage container and is exhausted to a second exhaust part.

As illustrated in FIG. 6, the EEPM system 10 according to the first preferred embodiment of the present invention includes a wafer storage container 100 in which wafers W are stored, a loading device 190 on which the wafer storage container 100 is loaded, equipment front end module (EFEM) 200 including a wafer transfer chamber 210 to which the wafer storage container 100 is connected, and a controller 300 allowing the downflow D to flow in the wafer transfer chamber 210 in the direction of the inside of the wafer storage container 100 or to flow in the direction opposite to the wafer storage container 100 in accordance with environmental conditions inside the wafer storage container 100.

Hereinafter, the wafer storage container 100 of the EFEM system 10 according to the first preferred embodiment of the present invention will be described.

The wafer storage container 100 provides a space in which the wafers W are stored, and as illustrated in FIGS. 6 and 7, includes a front opening (not illustrated) through which the wafers W enter and exit, an injection part 110 for injecting gas, a first exhaust part 120 for exhausting the injected gas and fumes on the wafers W, a concentration sensor 130 for measuring the concentration of noxious gas inside the wafer storage container 100, a humidity sensor 140 for measuring the humidity inside the wafer storage container, a flow sensor 150 for measuring the flow rate of the downflow D flowing in the direction of the inside of the wafer storage container 100, a temperature sensor 160 for measuring the temperature inside the wafer storage container 100, and a heater 170 provided in the wafer storage container 100 to increase the temperature inside the wafer storage container during operation.

The front opening is formed at a front side of the wafer storage container 100 such that the wafers W enter and exit through the front opening.

Therefore, when the wafer storage container 100 is placed on top of the loading device 190, the front opening communicates with an opening 213 formed in the wafer transfer chamber 210 of the EFEM 200, whereby the wafer storage container 100 and the wafer transfer chamber 210 are connected to each other.

The injection part 110 communicates with a loading device injection part (not illustrated) of the loading device 190 to function to inject the gas supplied from an external gas supply part (not illustrated) toward the wafers W stored in the wafer storage container 100. In this case, as illustrated in FIG. 9, the injection part 110 may be provided on each of rear and opposite side surfaces inside the wafer storage container 100.

As above, the gas injected by the injection part 110 forms an injection flow I.

The first exhaust part 120 communicates with the loading device exhaust part (not illustrated) of the loading device 190 to function to exhaust the gas injected into the wafer storage container 100 and the fumes on the wafers W to an external gas exhaust part (not illustrated). In this case, as illustrated in FIG. 6, the first exhaust part 120 may be provided at a lower side of the wafer storage container 100.

The concentration sensor 130 is provided inside the wafer storage container 100 and functions to measure the concentration of noxious gas inside the wafer storage container 100.

In this case, the noxious gas refers to a gas contained in the fumes on the wafers W. Examples of the noxious gas include ammonia (NH₃), chlorine (Cl₂), bromine (Br₂), and the like.

Therefore, the concentration sensor 130 may indirectly measure the concentration of the fumes by measuring the concentration of at least one of such noxious gases.

For example, when the wafers W stored in the wafer storage container 100 have undergone a process in which a large amount of ammonia (NH₃) remains, the concentration sensor 130 measures the concentration of ammonia (NH₃), thereby indirectly measuring the concentration of the fumes.

The humidity sensor 140 is provided inside the wafer storage container 100 and functions to measure the humidity inside the wafer storage container 100.

The flow sensor 150 measures the flow rate of the downflow D flowing in the direction of the inside of the wafer storage container 100.

The temperature sensor 160 is provided inside the wafer storage container 100 and functions to measure the temperature inside the wafer storage container 100.

The heater 170 is provided inside the wafer storage container 100 and functions to increase the temperature inside the wafer storage container 100.

Therefore, when the heater 170 operates, the temperature inside the wafer storage container 100 increases, and the humidity inside the wafer storage container 100 decreases.

Hereinafter, the loading device 190 of the EFEM system 10 according to the first preferred embodiment of the present invention will be described.

The loading device 190 loads the wafer storage container 100 thereon and functions to inject the gas supplied from the external gas supply part to the injection part of the wafer storage container 100 through the loading device injection part provided at the loading device 190 and to exhaust the gas exhausted from the first exhaust part 120 of the wafer storage container 100 and the fumes on the wafers W to the external gas exhaust part through the loading device exhaust part provided at the loading device 190.

The loading device 190 collectively refers to a device for loading the wafer storage container 100, such as a load port.

In addition, the wafer storage container 100 described above may be a mobile type in which the wafer storage container itself is moved by an automation system or a user and placed and loaded on the loading device 190, or may be a stationary type in which the wafer storage container is loaded on the loading device 190 while being coupled to the loading device 190 without being moved.

Hereinafter, the EFEM 200 of the EFEM system 10 according to the first preferred embodiment of the present invention will be described.

The EFEM 200 includes the wafer transfer chamber 210 connected to the wafer storage container 100, a delivery part 211 provided in an upper portion of the wafer transfer chamber 210 to deliver gas, and a second exhaust part 212 provided in a lower portion of the wafer transfer chamber 210 to exhaust the gas.

The wafer transfer chamber 210 refers to a space in which the wafers W are transferred in the EFEM 200 by a wafer transfer device (not illustrated) such as a robot arm.

The opening 213 is formed at one side of the wafer transfer chamber 210.

The opening 213 communicates with the front opening of the wafer storage container 100, whereby the wafer storage container 100 is connected to one side of the wafer transfer chamber 210.

In addition, process equipment (not illustrated) which performs a process, such as an etching, to the wafers W is connected to the other side of the wafer transfer chamber 210.

Therefore, the wafer transfer device may transfer the wafers W stored in the wafer storage container 100 to the process equipment to perform the process, or may transfer the wafers W having undergone the process in the process equipment to the wafer storage container 100. This transfer (or retransfer) of the wafers W is performed in the wafer transfer chamber 210.

The delivery part 211 is provided in the upper portion of the wafer transfer chamber 210 and functions to deliver the gas into the wafer transfer chamber 210.

In this case, the delivery part 211 may be a fan filter unit (FFU) including a delivery fan for delivering gas and a filter for filtering and cleaning the gas.

The gas delivered by the delivery part 211 flows to the lower portion of the wafer transfer chamber 210, thereby forming the downflow D.

The second exhaust part 212 is provided in the lower portion of the wafer transfer chamber 210 and functions to exhaust the gas in the wafer transfer chamber 210.

The second exhaust part 212 may be comprised of a plurality of second exhaust parts 212. In this case, as illustrated in FIG. 6, the plurality of second exhaust parts 212 may be comprised of a second-first exhaust part 212a, a second-second exhaust part 212b, a second-third exhaust part 212c, and a second-fourth exhaust part 212d.

Each of the second-first to second-fourth exhaust parts 212a to 212d may include a suction fan for generating a suction force.

Therefore, the controller 300 may individually operate the respective suction fans provided in the second-first to second-fourth exhaust parts 212a to 212d, respectively, thereby allowing the second-first to second-fourth exhaust parts 212a to 212d to achieve individual exhaust of the downflow D, gas, and the like.

In the foregoing description, the second exhaust part 212 has been described as an example that is comprised of the second-first to second-fourth exhaust parts 212a to 212d for ease of description. However, the number of the second exhaust parts 212 may vary as needed. In addition, in the following description, the control or operation of any one of the second-first to second-fourth exhaust parts 212a to 212d by the controller 300 may be understood as the control or operation of the second exhaust part 212.

Hereinafter, the controller 300 of the EFEM system 10 according to the first preferred embodiment of the present invention will be described.

As illustrated in FIG. 7, the controller 300 is connected to the concentration sensor 130, the humidity sensor 140, the flow sensor 150, the temperature sensor 160, the injection part 110, and the first exhaust part 120, the heater 170, the delivery part 211, the second-first exhaust part 212a, the second-second exhaust part 212b, the second-third exhaust part 212c, and the second-fourth exhaust part 212d.

The concentration sensor 130, the humidity sensor 140, the flow sensor 150, and the temperature sensor 160 are sensors for measuring environmental conditions inside the wafer storage container 100.

Hereinafter, the concentration sensor 130, the humidity sensor 140, the flow sensor 150, and the temperature sensor 160 are referred to as “measurement elements”.

The injection part 110 and the first exhaust part 120 are elements for controlling injection and exhaust of gas into and from the wafer storage container 100, respectively, and the heater 170 is an element for controlling the temperature inside the wafer storage container 100.

In addition, the delivery part 211 and the second exhaust part 212 are elements for controlling delivery and exhaust of gas into and from the wafer transfer chamber 210 of the EFEM 200, respectively.

Hereinafter, the injection part 110, the first exhaust part 120, the heater 170, the delivery part 211, and the second exhaust part 212 are referred to as “control elements”.

The controller 300 selectively controls the operation of the control elements in accordance with environmental conditions inside the wafer storage container 100 measured through at least one of the measurement elements, thereby functioning to control the downflow D in the wafer transfer chamber 210 to flow in the direction of the inside of the wafer storage container 100, or to flow in the direction opposite to the wafer storage container 100.

In this case, the controller 300 controls the operation of the control elements in accordance with whether values measured through the measurement elements are greater than or less than a concentration limit value, a humidity limit value, a flow rate limit value, and a temperature limit value that are preset in the controller 300.

Hereinafter, descriptions will be given of a fume removal operation for removing fumes from the wafers W and a moisture removal operation for removing moisture from the wafers W which are performed through the controller 300 of the EFEM system 10 according to the first preferred embodiment of the present invention having the above-described components.

First, the fume removal operation for removing fumes from the wafers W stored in the wafer storage container 100 of the EFEM system 10 will be described with reference to FIGS. 8 and 9.

The fume removal operation for removing fumes from the wafers W is performed when a lot of fumes remain on the wafers W.

Among the above-described components, the measurement element related to the fumes on the wafers W is the concentration sensor 130. Therefore, when a value measured by the concentration sensor 130, i.e., a measured concentration value of noxious gas is greater than the preset concentration limit value, the controller 300 determines that a lot of fumes remain on the wafers W.

As above, when the controller 300 determines that a lot of fumes remain on the wafers W, the controller 300 operates the injection part 110 and the first exhaust part 120 of the wafer storage container 100 and the delivery part 211 of the EFEM 200, and simultaneously stops the operation of the second-first to second-fourth exhaust parts 212a to 212d of the EFEM 200.

Since the injection part 110 and the delivery part 211 are operated, as illustrated in FIGS. 8 and 9, the injection flow I is generated inside the wafer storage container 100, while the downflow D is generated inside the wafer transfer chamber 210 of the EFEM 200.

In addition, since the first exhaust part 120 is operated while the second-first to second-fourth exhaust parts 212a to 212d are not operated, as illustrated in FIGS. 8 and 9, both the injection flow I and the downflow D are exhausted to the first exhaust part 120, whereby the downflow D in the wafer transfer chamber 210 flows in the direction of the inside of the wafer storage container 100.

Therefore, the gas of the injection flow I and the gas of the downflow D are exhausted to the first exhaust part 120 together with the fumes remaining on the wafers W, whereby the fumes on the wafers W are removed.

As above, since the fumes on the wafers W are removed by the use of both the injection flow I and the downflow D, a gas flow rate required for the removal of the fumes is sufficiently supplied, thereby making it possible to quickly achieve fume removal from the wafers W as compared to the related art.

In addition, since the downflow D is also used for removing the fumes, it is possible to minimize the waste of gas and thus to achieve fume removal from the wafers W.

In addition, in order to more effectively perform the above-described fume removal operation of the EFEM system 10, the controller 300 may increase a delivery flow rate of the delivery part 211.

In detail, when a value measured by the flow sensor 150 in a state in which the downflow D flows in the direction of the inside of the wafer storage container 100 and the fume removal operation is performed, i.e., the flow rate of the downflow D flowing in the direction of the inside of the wafer storage container 100 is less than the preset flow rate limit value, the controller 300 may increase the discharge flow rate of the delivery part 211, thereby increasing the flow rate of the downflow D flowing in the direction of the inside of the wafer storage container 100.

As such, as the flow rate of the downflow D flowing into the wafer storage container 100 becomes high, the time for removing the fumes on the wafers W becomes faster, and thus efficiency of removing the fumes on the wafer W is further increased.

Hereinafter, the moisture removal operation for removing moisture from the wafers W stored in the wafer storage container 100 of the EFEM system 10 will be described with reference to FIG. 10.

The moisture removal operation for removing moisture from the wafers W is performed when much moisture is present in the wafers W, i.e., when the humidity inside the wafer storage container 100 is high.

Among the above-described components, the measurement element related to the moisture in the wafers W is the humidity sensor 140. Therefore, when a value measured by the humidity sensor 140, i.e., a measured humidity value of the inside of the wafer storage container 100 is greater than the preset humidity limit value, the controller 300 determines that much moisture is present in the wafers W.

As above, when the controller 300 determines that much moisture is present in the wafers W, the controller 300 operates the injection part 110 of the wafer storage container 100, and the delivery part 211, the second-third exhaust part 212c, and the second-fourth exhaust part 212d of the EFEM 200, and simultaneously stops the operation of the first exhaust part 120 of the wafer storage container 100 and the second-first exhaust part 212a and the second-second exhaust part 212b of the EFEM 200.

Since the injection part 110 and the delivery part 211 are operated, as illustrated in FIG. 10, the injection flow I is generated inside the wafer storage container 100, while the downflow D is generated inside the wafer transfer chamber 210 of the EFEM 200.

In addition, since the second-third exhaust part 212c and the second-fourth exhaust part 212d are operated while the first exhaust part 120, the second-first exhaust part 212a, and the second-second exhaust part 212b are not operated, as illustrated in FIG. 10, the downflow D flows in the direction opposite to the wafer storage container 100.

In addition, although not illustrated in FIG. 10, the injection flow I generated by the injection part 110 also flows in the direction opposite to the wafer storage container 100 through the second exhaust part 212 on the opposite side.

As above, since the downflow D flows in the direction opposite to the wafer storage container 100, a region where the downflow D and the injection flow I meet each other in different flow directions in the vicinity of the front opening of the wafer storage container 100 (or in the vicinity of the opening 213) is not formed. Due thereto, the injection flow I can flow smoothly to a region in front of the wafers W, whereby a dead zone of the wafers W, in which gas fails to be injected, does not occur.

Therefore, a sufficient amount of gas can always flow to the wafers W, whereby the moisture in the wafers W can be effectively removed.

In other words, unlike the related art in which moisture removal from the wafers is not properly performed due to the downflow and the injection flow that meet each other in different flow directions, the EFEM system 10 according to the first preferred embodiment of the present invention can prevent possible dead zones of the wafers W by allowing the downflow D and the injection flow I to meet each other in the same flow direction, thereby achieving efficient moisture removal from the wafers W.

In addition, in order to more effectively perform the above-described moisture removal operation of the EFEM system 10, the controller 300 may operate the heater 170.

In detail, when a value measured by the temperature sensor 160 in a state in which the downflow D flows in the direction opposite to the wafer storage container 100 and the moisture removal operation is performed, i.e., the temperature inside the wafer storage container 100 is less than the preset temperature limit value, the controller 300 may operate the heater 170 to increase the temperature inside the wafer storage container 100.

As such, since the temperature inside the wafer storage container 100 is increased, the humidity inside the wafer storage container 100 decreases, whereby moisture removal from the wafers W can be more effectively achieved.

### EFEM System 10′ According to a Second Preferred Embodiment of the Present Invention

First, an EFEM system 10′ according to the second preferred embodiment of the present invention will be described with reference to FIGS. 11 to 17.

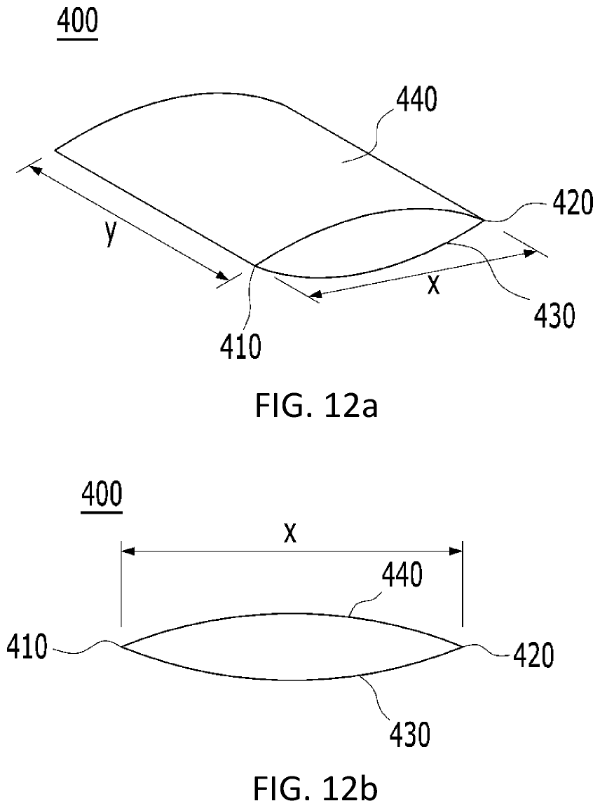

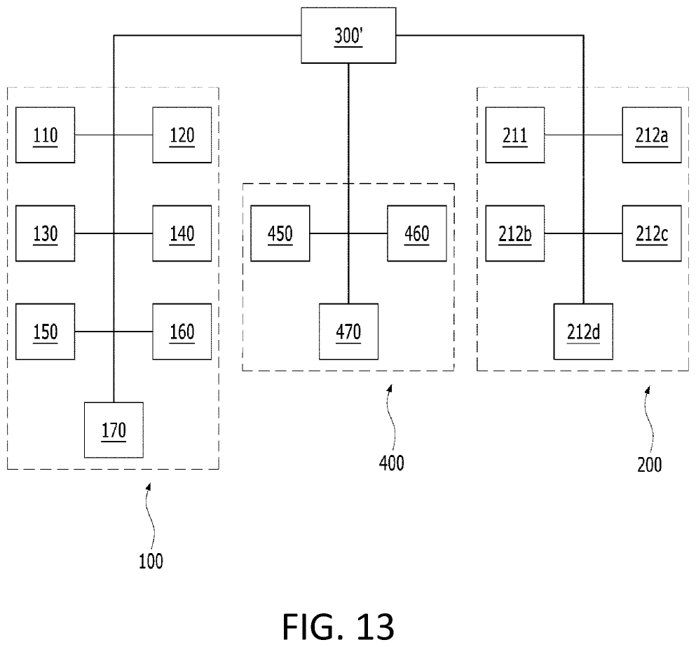

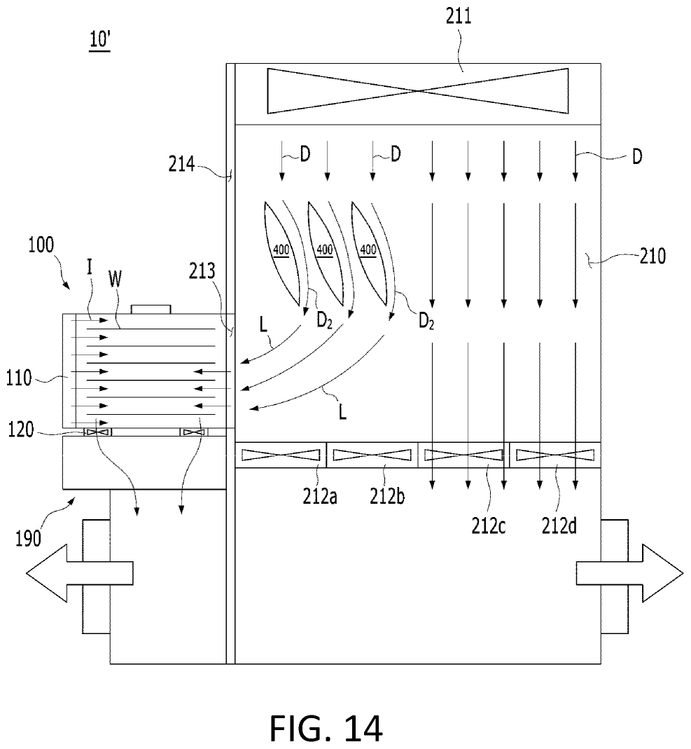

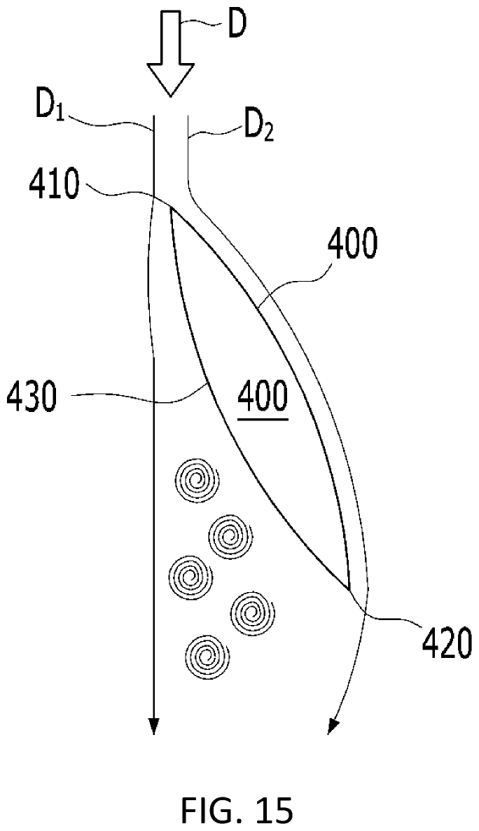

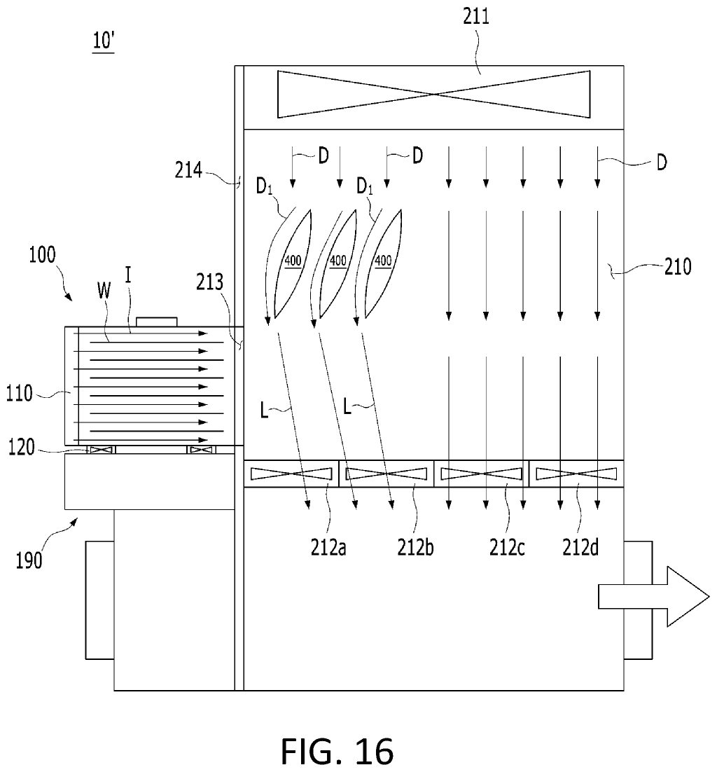

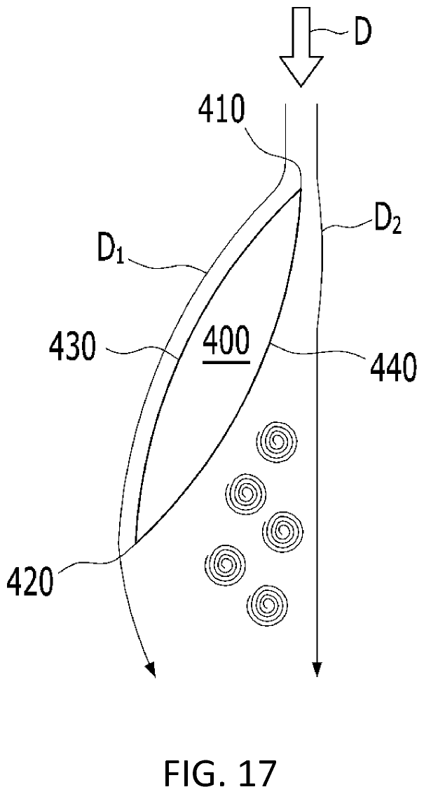

FIG. 11 is a view illustrating an EFEM system according to a second preferred embodiment of the present invention, FIGS. 12a and 12b are views illustrating an airflow control device of FIG. 11, FIG. 13 is a view illustrating a connection between a controller, measurement elements, and control elements of the EFEM system according to the second preferred embodiment of the present invention, FIG. 14 is a view illustrating that a downflow in a wafer transfer chamber of FIG. 11 flows into a wafer storage container and is exhausted to a first exhaust part, FIG. 15 is a view illustrating a flow change of the downflow due to the airflow control device in the state of FIG. 14, FIG. 16 is a view illustrating that the downflow in the wafer transfer chamber of FIG. 11 flows in a direction opposite to the wafer storage container and is exhausted to a second exhaust part, and FIG. 17 is a view illustrating a flow change of the downflow due to the airflow control device in the state of FIG. 16.

As illustrated in FIG. 11, the EEPM system 10′ according to the second preferred embodiment of the present invention includes a wafer storage container 100 in which wafers W are stored, a loading device 190 on which the wafer storage container 100 is loaded, equipment front end module (EFEM) 200 including a wafer transfer chamber 210 to which the wafer storage container 100 is connected, an airflow control device 400 provided in the wafer transfer chamber 210 to control the direction of a downflow D in accordance with the change in angle, and a controller 300′ allowing the downflow D in the wafer transfer chamber 210 to flow in the direction of the inside of the wafer storage container 100 or to flow in the direction opposite to the wafer storage container 100 in accordance with environmental conditions inside the wafer storage container 100.

As above, when comparing the EFEM system 10′ according to the second preferred embodiment of the present invention to the EFEM system 10 according to the first preferred embodiment of the present invention, there is a difference only in that the airflow control device 400 is provided in the wafer transfer chamber 210 and the controller 300′ controls the airflow control device 400 to allow the downflow D to flow in the direction of the inside of the wafer storage container 100 or to flow in the direction opposite to the wafer storage container 100, and the remaining components are the same. Therefore, a duplicate description will be omitted.

Hereinafter, the airflow control device 400 of the EFEM system 10′ according to the second preferred embodiment of the present invention will be described.

FIG. 12a is a perspective view illustrating the airflow control device 400 of FIG. 11, and FIG. 12b is a sectional view of the airflow control device 400 of FIG. 11.

However, for ease of explanation, in the following description, the “x” direction (the direction from a leading edge 410 to a trailing edge 420) illustrated in FIGS. 12a and 12b is referred to as a chordwise direction of the airflow control device 400, and the “y” direction illustrated in FIG. 12a is referred to as a spanwise direction.

As illustrated in FIG. 11, the airflow control device 400 is installed to be spaced apart from a wall surface 214 and functions to control the direction of the downflow D in accordance with the change in angle.

In addition, as illustrated in FIGS. 12a and 12b, the airflow control device 400 may have a wing shape with an airfoil, and includes the leading edge 410 striking the downflow D, a first convex portion 430 extending from the leading edge 410 to have a convex curvature in the direction of the wafer storage container 100 (or in the direction of the wall surface 214), a second convex portion 440 extending from the leading edge 410 to have a curvature convex in the direction opposite to the wafer storage container 100 (or in the direction opposite to the wall surface 214), and the trailing edge 420 extending from the first convex portion 430 and the second convex portion 440 and located opposite to the leading edge 410.

The leading edge 410 is formed at a front side of the airflow control device 400 and is a portion where the downflow D strikes directly when the downflow D is generated.

The trailing edge 420 is formed at a rear side of the airflow control device 400 and is a portion where the downflow D does not strike directly since the trailing edge 420 is located opposite to the leading edge 410.

The first convex portion 430 is formed on a first side surface of the airflow control device 400 to have a convex curvature in the direction of the wafer storage container 100 (or in the direction of the wall surface 214), while the second convex portion 440 is formed on a second side surface of the airflow control device 400 to have a convex curvature in the direction opposite to the wafer storage container 100 (or in the direction opposite to the wall surface 214).

In this case, the opposite side of the first side surface is the second side surface. Therefore, the second convex portion 440 is formed on the opposite side of the first convex portion 430.

The first convex portion 430 and the second convex portion 440 extend from the leading edge 410 to meet at the trailing edge 420. In other words, the leading edge 410, the first and second convex portions 430 and 440, and the trailing edge 420 form a continuous surface. As a result, as illustrated in FIG. 12b, a cross section of the airflow control device, i.e., an airfoil is formed.

The airflow control device 400 may include an airflow control device heater (460 of FIG. 13). The airflow control device heater functions to heat the airflow control device 400 to heat the downflow D or the like that flows in contact with the airflow control device 400, thereby increasing the temperature inside the wafer transfer chamber 210.

When the downflow D is heated by the airflow control device heater 460, the downflow D is further activated. This therefore provides an effect of increasing the flow velocity of the downflow D (because gas is activated when heated and the velocity thereof increases).

It is preferable that the airflow control device heater 460 is provided inside the airflow control device 400.

The airflow control device 400 may include a gas spraying part (470 of FIG. 13). The gas spraying part 470 is provided on the surface of the airflow control device 400 to spray gas, thereby functioning to supply an additional gas flow rate and simultaneously to allow gas flowing along the surface of the airflow control device, i.e., the downflow D to flow at a higher velocity.

It is preferable that the gas spraying part is provided on the surface of the airflow control wing, i.e., on at least one of the first convex portion 230 and the second convex portion 240. The gas spraying part may be provided on at least one of the first convex portion 230 and the second convex portion 240 in a form of a nozzle.

The airflow control device 400 having the above configuration is installed to be spaced apart from the wall surface 214 of the wafer transfer chamber 210.

In this case, in the airflow control device 400, it is preferable that the lowest portion (the trailing edge 420 in FIG. 11) of the airflow control device 400 is located above the front opening of the wafer storage container 100 and the opening 213 of the wall surface 214.

This is to prevent the airflow control device 400 from interfering with transfer of the wafer transfer device when the wafer transfer device transfers the wafers W.

In the airflow control device 400, it is preferable that the length of the airflow control device 400 in the spanwise direction (the length in the y direction illustrated in FIG. 12a) is equal to or greater than the horizontal length of the opening 213 of the wall surface 214.

This because when the length of the airflow control device 400 in the spanwise direction is less than the horizontal length of the opening 213 of the wall surface 241, i.e., when the length of the airflow control device 400 in the spanwise direction is smaller than the horizontal length of the opening 213 of the wall surface 241, the downflow D flows by being bent on the left and right sides of the airflow control device 400 and thus it is not easy to control the direction of the downflow D, such as flowing in the direction of the inside of the wafer storage container 100, or flowing in the direction opposite to the wafer storage container 100.

The airflow control device 400 may be installed to be tiltable, whereby the change in angle of the airflow control device 400 may be easily performed.

In this case, tilting, i.e., the change in angle of the airflow control device 400 is performed by a driving part 450, and driving part 450 is controlled by the controller 300.

Therefore, the angle of the air flow control device 400 may be controlled in accordance with the driving of the driving part 450 through the controller 300. For example, as illustrated in FIGS. 14 and 15, the angle of the air flow control device may be controlled such that the trailing edge 420 is directed in the direction opposite to the wafer storage container 100 (or in the direction opposite to the wall surface 214). Alternatively, as illustrated in FIGS. 16 and 17, the angle of the air flow control device may be controlled such that the trailing edge 420 is directed in the direction of the wafer storage container 100 (or in the direction of the wall surface 214).

In the following description, as illustrated in FIGS. 14 and 15, the case where the angle of the airflow control device 400 is controlled such that the trailing edge 420 is directed in the direction opposite to the wafer storage container 100 (or in the direction opposite to the wall surface 214) is referred to as a “first direction angle”. As illustrated in FIGS. 16 and 17, the case where the angle of the air flow control device is controlled such that the trailing edge 420 is directed in the direction of the wafer storage container 100 (or in the direction of the wall surface 214) is referred to as a “second direction angle”.

In this case, in the case of the first direction angle, it is most preferable that at an angle in which the trailing edge 420 is directed in the direction opposite to the wafer storage container 100, the angle between a vertical axis connecting the upper and lower sides of the wafer transfer chamber 210 and a central axis of the airflow control device 400 is 25°.

In addition, in the case of the second direction angle, it is most preferable that at an angle in which the trailing edge 420 is directed in the direction of the inside of the wafer storage container 100, the angle between the vertical axis connecting the upper and lower sides of the wafer transfer chamber 210 and the central axis of the airflow control device 400 is 25°.

The airflow control device 400 may be provided as a plurality of airflow control devices. The plurality of airflow control devices 400 may be installed to have a height difference.

The height difference of the plurality of airflow control devices 400 refers that the heights of trailing edges 420 of the plurality of airflow control devices 400 are positioned differently from upon each other installation.

In this case, the plurality of airflow control devices 400 may be installed such that the heights of the trailing edges 420 of the plurality of airflow control devices 400 gradually decrease in the direction of the wall surface 214. On the contrary, the plurality of airflow control devices 400 may be installed such that the heights of the trailing edges 420 of the plurality of airflow control devices 400 gradually decrease in the direction opposite to the wall surface 214.

As described above, since the plurality of airflow control devices 400 is installed to have a height difference from each other, it is possible to more easily control the downflow D in a desired direction.

Hereinafter, the controller 300′ of the EFEM system 10′ according to the second preferred embodiment of the present invention will be described.

As illustrated in FIG. 15, the controller 300′ is connected to the concentration sensor 130, the humidity sensor 140, the flow sensor 150, the temperature sensor 160, the injection part 110, and the first exhaust part 120, the heater 170, the delivery part 211, the second-first exhaust part 212a, the second-second exhaust part 212b, the second-third exhaust part 212c, the second-fourth exhaust part 212d, the driving part 450, the airflow control device heater 460, and the gas spraying part 470.

The concentration sensor 130, the humidity sensor 140, the flow sensor 150, and the temperature sensor 160 are sensors for measuring environmental conditions inside the wafer storage container 100.

Hereinafter, the concentration sensor 130, the humidity sensor 140, the flow sensor 150, and the temperature sensor 160 are referred to as “measurement elements”.

The injection part 110 and the first exhaust part 120 are elements for controlling injection and exhaust of gas into and from the wafer storage container 100, respectively, and the heater 170 is an element for controlling the temperature inside the wafer storage container 100.

In addition, the delivery part 211 and the second-first to second-fourth exhaust parts 212a to 212d are elements for controlling delivery and exhaust of gas into and from the wafer transfer chamber 210 of the EFEM 200, respectively.

Hereinafter, the injection part 110, the first exhaust part 120, the heater 170, the delivery part 211, the second-first to second-fourth exhaust parts 212a to 212d, the driving part 450, the airflow control device heater 460, and the gas spraying part 470 are referred to as “control elements”.

The controller 300′ selectively controls the operation of the control elements in accordance with environmental conditions inside the wafer storage container 100 measured through at least one of the measurement elements, thereby functioning to control the downflow D in the wafer transfer chamber 210 to flow in the direction of the inside of the wafer storage container 100, or to flow in the direction opposite to the wafer storage container 100.

In this case, the controller 300′ controls the operation of the control elements in accordance with whether values measured through the measurement elements are greater than or less than a concentration limit value, a humidity limit value, a flow rate limit value, and a temperature limit value that are preset in the controller 300′.

Hereinafter, descriptions will be given of a fume removal operation for removing fumes from the wafers W and a moisture removal operation for removing moisture from the wafers W which are performed through the controller 300′ of the EFEM system 10′ according to the second preferred embodiment of the present invention having the above-described components.

First, the fume removal operation for removing fumes from the wafers W stored in the wafer storage container 100 of the EFEM system 10′ will be described with reference to FIGS. 14 and 15.

The fume removal operation for removing fumes from the wafers W is performed when a lot of fumes remain on the wafers W.

Among the above-described components, the measurement element related to the fumes on the wafers W is the concentration sensor 130. Therefore, when a value measured by the concentration sensor 130, i.e., a measured concentration value of noxious gas is greater than the preset concentration limit value, the controller 300′ determines that a lot of fumes remain on the wafers W.

As above, when the controller 300′ determines that a lot of fumes remain on the wafers W, the controller 300′ operates the injection part 110 and the first exhaust part 120 of the wafer storage container 100 and the delivery part 211, the second-third exhaust part 212c, and the second-fourth exhaust part 212d of the EFEM 200, and simultaneously stops the operation of the second-first exhaust part 212a and the second-second exhaust part 212b of the EFEM 200.

In addition, the controller 300′ operates the driving part 450 to control the angle of each of the airflow control devices 400 becomes the first direction angle as illustrated in FIGS. 14 and 15.

Since the injection part 110 and the delivery part 211 are operated, as illustrated in FIG. 14, the injection flow I is generated inside the wafer storage container 100, while the downflow D is generated inside the wafer transfer chamber 210 of the EFEM 200.

In addition, since the angle of each of the airflow control devices 400 becomes the first direction angle, the trailing edge 420 of each of the airflow control devices 400 is directed in the direction opposite to the wafer storage container 100 (or in the direction opposite to the wall surface 214).

In this case, as illustrated in FIG. 15, the downflow D strikes the trailing edge 410 of each of the airflow control devices 400 and then flows separately to the surfaces of the first convex portion 430 and the second convex portion 440.

In the case of airflow flowing to the surface of the second convex portion 440 (hereinafter referred to as “second convex portion flow D2”), since the angle of each of the airflow control devices 400 is formed at the first direction angle, the second convex portion flow D2 flows along the surface of the second convex portion 440, and since the second convex portion 440 has a convex curvature, a Coanda effect occurs.

When the Coanda effect occurs, the second convex portion flow D2 flows in the direction of the wafer storage container 100 (or in the direction of the wall surface 214) along the curvature of the second convex portion 440, and the flow velocity thereof further increases.

Therefore, even if the second convex portion flow D2 leaves the trailing edge 420 of each of the airflow control devices 400, a high flow velocity can be maintained, thereby forming a laminar flow L of high flow velocity.

Meanwhile, in the case of airflow flowing to the surface of the first convex portion 430 (hereinafter referred to as “first convex portion flow D1”), since the angle of each of the airflow control devices is formed at the first direction angle, separation flow occurs. Therefore, the first convex portion flow D1 forms turbulence at a lower portion of the first convex portion 430, and, due thereto, the flow velocity thereof decreases.

In other words, the first convex portion flow D1 is separated from each of the airflow control devices 400 due to the separation flow and does not form a laminar flow but turbulence unlike the second convex portion flow D2.

This is because the first convex portion flow D1 flowing along the first convex portion 430 is converted from a laminar flow into drag force on the basis of a transition point (or separation point) by the separation flow principle. In this case, the flow velocity at the transition point (or separation point) converges to “0”.

Therefore, a relationship of “flow velocity of the second convex portion flow D2>flow velocity of the downflow D>flow velocity of the first convex portion flow D1” is fulfilled.

As described above, since the angle of each of the airflow control devices 400 is controlled to the first direction angle, a part of the downflow D is separated into the first convex portion flow D1 and the second convex portion flow D2 while passing through the airflow control device 400. As a result, as illustrated in FIG. 14, the laminar flow L is formed and flows in the direction of the wafer storage container 100 (or in the direction of the wall surface 214).

In addition, since the first exhaust part 120 is operated while the second-first exhaust part 212a and the second-second exhaust part 212b are not operated, the downflow D having flowed in the direction of the wafer storage container 100 is exhausted to the first exhaust part 120 together with the injection flow I. Therefore, the downflow D flows in the direction of the inside of the wafer storage container 100.

As above, since the downflow D flows in the direction of the inside of the wafer storage container 100, gas of the injection flow I and the gas of the downflow D are exhausted to the first exhaust part 120 together with the fumes remaining on the wafers W, whereby the fumes on the wafers W are removed.

As such, since the fumes on the wafers W are removed by the use of both the injection flow I and the downflow D, a gas flow rate required for the removal of the fumes is sufficiently supplied, thereby making it possible to quickly achieve fume removal from the wafers W as compared to the related art.

In addition, since the downflow D is also used for removing the fumes, it is possible to minimize the waste of gas and thus to achieve fume removal from the wafers W.

In addition, since the downflow D flowing in the direction of the inside of the wafer storage container 100 by the airflow control devices 400 flows while forming the laminar flow L, the flow velocity thereof is high and thus a large flow rate can flow during the same time. Therefore, the EFEM system 10′ according to the second preferred embodiment of the present invention can remove the fumes on the wafer W at a faster time than the EFEM system 10 according to the first preferred embodiment of the present invention.

In addition, in order to more effectively perform the above-described moisture removal operation of the EFEM system 10′, the controller 300′ may operate at least one of the airflow control device heater 460 and the gas spraying part 470, thereby increasing the flow rate of the downflow D flowing in the direction of the inside of the wafer storage container 100.

In detail, when a value measured by the flow sensor 150 in a state in which the downflow D flows in the direction of the inside of the wafer storage container 100 and the fume removal operation is performed, i.e., the flow rate of the downflow D flowing in the direction of the inside of the wafer storage container 100 is less than the preset flow rate limit value, the controller 300′ may operate at least one of the airflow control device heater 460 or the gas spraying part 470.

When the airflow control device heater 460 is operated, the temperature inside the wafer transfer chamber 210 is increased, and thus the downflow D is heated to be activated. Therefore, the flow velocity of the downflow D flowing into the wafer storage container 100 becomes high, and thus a large flow rate can flow into the wafer storage container 100 during the same time.

When the gas spraying part 470 is operated, not only an additional gas flow rate is supplied through the gas spraying part 470, but also the Coanda effect occurring on the surface of the second convex portion 440 is further maximized. Therefore, conversion of the second convex portion flow D2 into the laminar flow L is made effectively. Therefore, the flow velocity of the downflow D flowing into the wafer storage container 100 becomes high, and thus a large flow rate can flow into the wafer storage container 100 during the same time.

As such, as the flow rate of the downflow D flowing into the wafer storage container 100 becomes high, the time for removing the fumes on the wafers W becomes faster, and thus efficiency of removing the fumes on the wafer W is further increased.

Hereinafter, the moisture removal operation for removing moisture from the wafers W stored in the wafer storage container 100 of the EFEM system 10′ will be described with reference to FIGS. 16 and 17.

The moisture removal operation for removing moisture from the wafers W is performed when much moisture is present in the wafers W, i.e., when the humidity inside the wafer storage container 100 is high.

Among the above-described components, the measurement element related to the moisture in the wafers W is the humidity sensor 140. Therefore, when a value measured by the humidity sensor 140, i.e., a measured humidity value of the inside of the wafer storage container 100 is greater than the preset humidity limit value, the controller 300′ determines that much moisture is present in the wafers W.

As above, when the controller 300′ determines that much moisture is present in the wafers W, the controller 300′ operates the injection part 110 of the wafer storage container 100, and the delivery part 211 and the second-first to second-fourth exhaust parts 212a to 212d of the EFEM 200, and simultaneously stops the operation of the first exhaust part 120 of the wafer storage container 100.

In addition, the controller 300′ operates the driving part 450 to control the angle of each of the airflow control devices 400 becomes the second direction angle as illustrated in FIGS. 16 and 17.

Since the injection part 110 and the delivery part 211 are operated, as illustrated in FIG. 16, the injection flow I is generated inside the wafer storage container 100, while the downflow D is generated inside the wafer transfer chamber 210 of the EFEM 200.

In addition, since the angle of each of the airflow control devices 400 becomes the second direction angle, the trailing edge 420 of each of the airflow control devices 400 is directed in the direction of the wafer storage container 100 (or in the direction of the wall surface 214).

In this case, as illustrated in FIG. 17, the downflow D strikes the trailing edge 410 of each of the airflow control devices 400 and then flows separately to the surfaces of the first convex portion 430 and the second convex portion 440.

Since the angle of each of the airflow control devices 400 is formed at the second direction angle, the first convex portion flow D1 flowing to the surface of the first convex portion 430 along the surface of the first convex portion 430, and since the first convex portion 430 has a convex curvature, the Coanda effect occurs.

When the Coanda effect occurs, the first convex portion flow D1 flows in the direction opposite to the wafer storage container 100 (or in the direction opposite to the wall surface 214) along the curvature of the first convex portion 430, and the flow velocity thereof further increases.

Therefore, even if the first convex portion flow D1 leaves the trailing edge 420 of each of the airflow control devices 400, a high flow velocity can be maintained, thereby forming a laminar flow L of high flow velocity.

On the other hand, in the case of the second convex portion flow flowing to the surface of the second convex portion 440, since the angle of each of the airflow control devices 400 is formed at the second direction angle, separation flow occurs. Therefore, the second convex portion flow D2 forms turbulence at a lower portion of the second convex portion 440, and due thereto, the flow velocity thereof decreases.

In other words, the second convex portion flow D2 is separated from each of the airflow control devices 400 due to the separation flow and does not form a laminar flow but turbulence unlike the first convex portion flow D1.

This is because the second convex portion flow D2 flowing along the second convex portion 440 is converted from a laminar flow into drag force on the basis of a transition point (or separation point) by the separation flow principle. In this case, the flow velocity at the transition point (or separation point) converges to “0”.

Therefore, a relationship of “flow velocity of the first convex portion flow D1>flow velocity of the downflow D>flow velocity of the second convex portion flow D2” is fulfilled.

As described above, since the angle of each of the airflow control devices 400 is controlled to the second direction angle, a part of the downflow D is separated into the first convex portion flow D1 and the second convex portion flow D2 while passing through the airflow control device 400. As a result, as illustrated in FIG. 16, the laminar flow L is formed and flows in the direction opposite to the wafer storage container 100 (or in the direction opposite to the wall surface 214).

In addition, since the second-first to second-fourth exhaust parts 212a to 212d are operated while the first exhaust part 120 is not operated, as illustrated in FIG. 16, the downflow D flows in the direction opposite to the wafer storage container 100.

In addition, although not illustrated in FIG. 16, the injection flow I generated by the injection part 110 also flows in the direction opposite to the wafer storage container 100 through the second-first exhaust part 212a which is the closest one among the second-first to second-fourth exhaust parts 212a to 212d.

As above, since the downflow D flows in the direction opposite to the wafer storage container 100, a region where the downflow D and the injection flow I meet each other in different flow directions in the vicinity of the front opening of the wafer storage container 100 (or in the vicinity of the opening 213) is not formed. Due thereto, the injection flow I can flow smoothly to a region in front of the wafers W, whereby a dead zone of the wafers W, in which gas fails to be injected, does not occur.

Therefore, a sufficient amount of gas can always flow to the wafers W, whereby the moisture in the wafers W can be effectively removed.

In other words, unlike the related art in which moisture removal from the wafers is not properly performed due to the downflow and the injection flow that meet each other in different flow directions, the EFEM system 10′ according to the second preferred embodiment of the present invention can prevent possible dead zones of the wafers W by allowing the downflow D and the injection flow I to meet each other in the same flow direction, thereby achieving efficient moisture removal from the wafers W.

In addition, since the downflow D flowing in the direction opposite to the wafer storage container 100 by the airflow control devices 400 flows while forming the laminar flow L, the downflow D does not flow in the direction of the inside of the wafer storage container 100 due to high flow velocity thereof even if exhausted by the second-first exhaust part 212a and the second-second exhaust part 212b. In addition, since the flow velocity of the second convex portion flow D2 is low, the second convex portion flow D2 is easily exhausted by the second-third exhaust part 212c and the second-fourth exhaust part 212d.

In other words, due to the downflow D separated into the first convex portion flow D1 and the second convex portion flow D2 by the airflow control devices 400, and due to the characteristics of the first convex portion flow D1 and the second convex portion flow D2, exhaust of the downflow D in the direction opposite to the wafer storage container 100 through the second-first to second-fourth exhaust parts 212a to 212d can be very easily performed.

Therefore, the EFEM system 10′ according to the second preferred embodiment of the present invention can more easily prevent that the downflow D and the injection flow I meet each other in the vicinity of the front opening of the wafer storage container 100 (or in the vicinity of the opening 213) as compared to the EFEM system 10 according to the first preferred embodiment of the present invention. Due thereto, it is possible to achieve more effective moisture removal from the wafer W.

In addition, in order to more effectively perform the above-described moisture removal operation of the EFEM system 10′, the controller 300′ may operate the heater 170.

In detail, when a value measured by the temperature sensor 160 in a state in which the downflow D flows in the direction opposite to the wafer storage container 100 and the moisture removal operation is performed, i.e., the temperature inside the wafer storage container 100 is less than the preset temperature limit value, the controller 300′ may operate the heater 170 to increase the temperature inside the wafer storage container 100.

As such, since the temperature inside the wafer storage container 100 is increased, the humidity inside the wafer storage container 100 decreases, whereby moisture removal from the wafers W can be more effectively achieved.

### EFEM System According to a Third Preferred Embodiment of the Present Invention

Hereinafter, an EFEM system according to the third preferred embodiment of the present invention will be described.

The EFEM system according to the third preferred embodiment of the present invention includes a wafer storage container in which wafers are stored, a loading device on which the wafer storage container is loaded, an EFEM including a wafer transfer chamber to which the wafer storage container is connected, an airflow control device provided in the wafer transfer chamber to control the direction of a downflow in accordance with the change in angle, and a controller controlling the downflow in the wafer transfer chamber in accordance with environmental conditions inside the wafer transfer chamber.

As above, when comparing the EFEM system according to the third preferred embodiment of the present invention to the EFEM system 10′ according to the second preferred embodiment of the present invention, there is a difference only in that the controller controls the downflow in the wafer transfer chamber in accordance with environmental conditions inside the wafer transfer chamber, and the remaining components are the same. Therefore, a duplicate description will be omitted.

In addition, in the case of the airflow control device of the EFEM system according to the third preferred embodiment of the present invention, the components and the shape thereof are the same as those of the airflow control device 400 of the EFEM system 10′ according to the second preferred embodiment of the present invention, but there is a difference in terms of functionality.

In detail, the airflow control device 400 of the IFMP system 10′ according to the second preferred embodiment of the present invention controls the direction of the downflow D in accordance with the change in the angle thereof, thereby functioning to allow the downflow D to flow in the direction of the inside of the wafer storage container 100, or to flow in the direction opposite to the wafer storage container 100.

On the other hand, the airflow control device of the EFPM system according to the third preferred embodiment of the present invention has the same functionality in terms of controlling the direction of the downflow in accordance with the change in the angle thereof. However, there is a difference in terms of functionality in that the downflow inside the wafer transfer chamber is flowed in the outward direction of the wafer transfer chamber or in the inward direction of the wafer transfer chamber.

As above, since the airflow control device of the EFEM system according to the third preferred embodiment of the present invention allows the downflow inside the wafer transfer chamber to flow in the outward direction of the wafer transfer chamber or in the inward direction of the wafer transfer chamber in accordance with environmental conditions inside the wafer transfer chamber, there is an effect of minimizing possible dead zones inside the wafer transfer chamber, in which the downflow fails to flow, and ensuring a uniform flow of the downflow.

In addition to the above function and effect of the airflow control device, unlike the wafer storage containers 100 of the EFEM systems 10 and 10′ according to the first and second preferred embodiments of the present invention described above, the wafer storage container of the EFEM system according to the third preferred embodiment of the present invention may be provided in a form in which gas is not injected into and exhausted from the wafer storage container.

This is because, since the EFEM system according to the third preferred embodiment of the present invention changes environmental conditions inside the wafer transfer chamber, i.e., environmental conditions inside the EFEM by controlling the flow direction of the downflow in the wafer transfer chamber in accordance with environmental conditions inside the wafer transfer chamber, this objective can be achieved without considering environmental conditions inside the wafer storage container.

Hereinafter, the controller of the EFEM system according to the third preferred embodiment of the present invention will be described.

The controller is connected to a concentration sensor, a humidity sensor, a flow sensor, a temperature sensor, a heater, a delivery part, a second-first exhaust part, a second-second exhaust part, a second-third exhaust part, a second-fourth exhaust part, a driving part, an airflow control device heater, and a gas spraying part.

The concentration sensor, the humidity sensor, the flow sensor, and the temperature sensor are sensors for measuring environmental conditions inside the wafer storage container of the EFEM.

In addition, a plurality of heaters, concentration sensors, humidity sensors, flow sensors, and temperature sensors may be provided inside the wafer transfer chamber.

Hereinafter, the concentration sensor, the humidity sensor, the flow sensor, and the temperature sensor are referred to as “measurement elements”.

The heater is an element for controlling the temperature inside the EFEM, i.e., inside the wafer transfer chamber. The delivery part and the second-first to second-fourth exhaust parts are elements for controlling gas delivery and exhaust into and from the EFEM, i.e., into and from the wafer transfer chamber, respectively.

Hereinafter, the heater, the delivery part, the second-first to second-fourth exhaust parts, the driving part, the airflow control device heater, and the gas spraying part are referred to as “control elements”.

The controller selectively controls the operation of the control elements in accordance with environmental conditions inside the wafer transfer chamber of the EFEM measured by at least one of the measurement elements and thus to allow the downflow inside the wafer transfer chamber to flow in the outward direction of the wafer transfer chamber or in the inward direction of the wafer transfer chamber, thereby functioning to minimize possible dead zones inside the wafer transfer chamber, in which the downflow fails to flow, and to ensure a uniform flow of the downflow.

In this case, the controller controls the operation of the control elements in accordance with whether values measured through the measurement elements are greater than or less than a concentration limit value, a humidity limit value, a flow rate limit value, and a temperature limit value that are preset in the controller.

Of course, the concentration limit value, the humidity limit value, the flow rate limit value, and the temperature limit value preset in the controller refer to a concentration limit value, a humidity limit value, a flow rate limit value, and a temperature limit value of the inside of the wafer transfer chamber.

Hereinafter, an operation of controlling environmental conditions inside the wafer transfer chamber of the EFEM system according to the third preferred embodiment of the present invention having the above-described components will be described.

The operation of controlling environmental conditions inside the wafer transfer chamber of the EFEM system is performed through the controller.

First, the control of environmental conditions inside the wafer transfer chamber by the concentration sensor among the measurement elements will be described.

When a concentration value measured by any one concentration sensor of the plurality of concentration sensors is greater than the preset concentration limit value, the controller determines that the flow of the downflow is not properly performed in an area (hereinafter referred to as a “flow required area”) in which the any one concentration sensor is located inside the wafer transfer chamber.

Therefore, the controller operates the driving part to control the angle of the airflow control device, thereby allowing the downflow to flow through the airflow control device to the flow required area, and operates an exhaust part located close to the flow required area among the second-first to second-fourth exhaust parts to smoothly exhaust the downflow, i.e., gas.

In other words, the controller allows the downflow to intensively flow to the flow required area where the concentration value greater than the concentration limit value is measured and simultaneously allows intensive exhaust of the flowed downflow, thereby reducing the concentration value, i.e., pollution degree, of the flow required area.

As above, since the flow of the downflow is controlled through the controller, there is an effect in that generation of possible dead zones inside the wafer transfer chamber can be suppressed, and in that removal of contaminants (i.e., fumes) can be smoothly achieved through a uniform flow of downflow inside the wafer transfer chamber.

Hereinafter, the control of environmental conditions inside the wafer transfer chamber by the humidity sensor among the measurement elements will be described.

When a humidity value measured by any one humidity sensor of the plurality of humidity sensors is greater than the preset humidity limit value, the controller determines that the humidity is high in an area (hereinafter referred to as a “heating required area”) in which the any one humidity sensor is located inside the wafer transfer chamber.

Therefore, the controller operates the driving part to control the angle of the airflow control device, thereby allowing the downflow to flow through the airflow control device to the heating required area, and operates a heater located close to the heating required area among the plurality of heaters to increase the temperature in the heating required area.

In other words, the controller allows the downflow to intensively flow to the heating required area where the humidity value greater than the humidity limit value is measured and simultaneously increases temperature, thereby removing the humidity value, i.e., moisture, of the heating required area.

As above, since the flow of the downflow and temperature heating inside the wafer transfer chamber are performed through the controller, humidity inside the wafer transfer chamber can be reduced or moisture can be removed. Therefore, there is an effect that oxidation due to moisture occurring in the wafers transferred inside the wafer transfer chamber is prevented.

In addition, the controller may operate an airflow control device heater located close to the heating required area as well as the heater, thereby heating the inside of the wafer transfer chamber and simultaneously heating the downflow, whereby moisture inside the wafer transfer chamber may be removed.

In addition, when heating the inside of the wafer transfer chamber through the heater or the airflow control device to remove moisture as above, if a temperature sensor in which a measured temperature value is greater than the temperature limit value among the plurality of temperature sensors exists, the controller may stop the operation of a heater or an airflow control device heater located in a corresponding area, thereby allowing the temperature inside the wafer transfer chamber to be maintained at an appropriate temperature.

Hereinafter, the control of environmental conditions inside the wafer transfer chamber by the flow sensor among the measurement elements will be described.

When a flow rate value measured by any one flow sensor of the plurality of flow sensors is less than the preset flow rate limit value, the controller determines that the flow of the downflow is not properly performed in an area (hereinafter referred to as a “flow rate supply required area”) in which the any one flow sensor is located inside the wafer transfer chamber.

Therefore, the controller operates the driving part to control the angle of the airflow control device, thereby allowing the downflow to flow to the flow rate supply required area through the airflow control device to allow the downflow, i.e., gas to be supplied at a sufficient flow rate.

In other words, the controller allows the downflow to intensively flow to the flow rate supply required area where the flow rate value less than the flow rate limit value is measured, thereby increasing a supply flow rate of the flow rate supply required area.

As above, since the flow of the downflow is controlled through the controller, it is possible to suppress generation of possible dead zones inside the wafer transfer chamber, and to achieve a uniform flow of downflow inside the wafer transfer chamber.

In addition, since the amount of gas delivered or injected from the delivery part or the gas spraying part is increased, it is possible to easily increase the amount of the downflow (or gas) supplied (or flowed) to the flow rate supply required area.

Although the first to third preferred embodiments of the present invention have been described for illustrative purposes, those skilled in the art will appreciate that various modifications, additions and substitutions are possible, without departing from the scope and spirit of the invention as disclosed in the accompanying claims.

### DESCRIPTION OF THE REFERENCE NUMERALS IN THE DRAWINGS

[Reference Numerals of FIGS. 1 to 6]
10: EFEM
50: wafer storage container
60: loading device
150: wafer transfer chamber
151: wall surface
152: opening
153: gas delivery part
154: gas suction part
200: airflow control wing
210: leading edge
220: trailing edge
230: first convex portion
240: second convex portion
W: wafer
D: downflow
D1: first convex portion flow
D2: second convex portion flow
I: injection flow
L: laminar flow

[Reference Numerals of FIGS. 6 to 17]
10, 10′: EFEM system
100: wafer storage container
110: injection part
120: first exhaust part
130: concentration sensor
140: humidity sensor
150: flow sensor
160: temperature sensor
170: heater
190: loading device
200: EFEM
210: wafer transfer chamber
211: delivery part
212: second exhaust part
212a: second-first exhaust part
212b: second-second exhaust part
212c: second-third exhaust part
212d: second-fourth exhaust part
213: opening
214: wall surface
300, 300′: controller
400: airflow control device
410: leading edge
420: trailing edge
430: first convex portion
440: second convex portion
450: driving part
460: airflow control device heater
470: gas spraying part
D: downflow
D1: first convex portion flow
D2: second convex portion flow
I: injection flow
L: laminar flow
W: wafer

1-24. (canceled)

25. An EFEM that is configured such that a wafer storage container is connected to an opening formed in a wall surface of the EFEM and a wafer transfer chamber is provided therein, the EFEM comprising:
a gas delivery part provided in an upper portion of the wafer transfer chamber and delivering gas into the wafer transfer chamber;
a gas suction part provided in a lower portion of the wafer transfer chamber and suctioning the gas inside the wafer transfer chamber; and
an airflow control wing provided between the gas delivery part and the gas suction part, installed to be spaced apart from the wall surface, and controlling a downflow flowing to a space defined between the airflow control wing and the wall surface.

26. The EFEM of claim 25, wherein an element of the downflow controlled by the airflow control wing is a flow velocity or direction.

27. The EFEM of claim 25, wherein the airflow control wing has a curvature.

28. The EFEM of claim 25, wherein the airflow control wing includes a first convex portion formed convexly in a direction of the wall surface.

29. The EFEM of claim 25, wherein the airflow control wing includes a second convex portion formed convexly in a direction opposite to the wall surface.

30. The EFEM of claim 25, wherein a length of the airflow control wing in a spanwise direction is equal to or greater than a horizontal length of the opening.

31. The EFEM of claim 25, wherein the airflow control wing includes a leading edge striking the downflow, a first side surface extending from the leading edge to have a curvature convex in a direction of the wall surface, a second side surface extending from the leading edge to have a curvature convex in a direction opposite to the wall surface, and a trailing edge extending from the first and second side surfaces and located opposite to the leading edge.

32. The EFEM of claim 25, wherein a trailing edge of the airflow control wing is inclined toward the wall surface.

33. The EFEM of claim 25, wherein the airflow control wing is provided as a plurality of airflow control wings, and
the plurality of airflow control wings is installed to have a height difference.

34. The EFEM of claim 25, wherein the suction part is comprised of a plurality of suction parts that can perform individual suction, and
the plurality of suction parts is configured to control a direction of the downflow separated from the airflow control wing.

35. The EFEM of claim 25, wherein the airflow control wing further includes: a heater provided at the airflow control wing.

36. The EFEM of claim 25, wherein the airflow control wing includes: a gas spraying part provided at the airflow control wing.

37. An EFEM system including a wafer transfer chamber, wherein the EFEM system controls a downflow of the wafer transfer chamber in accordance with environmental conditions inside the wafer transfer chamber.

38. An EFEM system including a wafer storage container in which wafers are stored and an EFEM including a wafer transfer chamber to which the wafer storage container is connected, the EFEM system comprising:
a controller allowing the downflow in the wafer transfer chamber to flow in a direction of inside of the wafer storage container or to flow in a direction opposite to the wafer storage container in accordance with the environmental conditions inside the wafer storage container.

39. The EFEM system of claim 38, further comprising:
a concentration sensor measuring a concentration of noxious gas inside the wafer storage container; and
a first exhaust part provided inside the wafer storage container, wherein
when a value measured by the concentration sensor is greater than a preset concentration limit value, the controller operates the first exhaust part to allow the downflow in the direction of the inside of the wafer storage container.

40. The EFEM system of claim 38, further comprising:
a humidity sensor measuring a humidity inside the wafer storage container; and
a second exhaust part provided in the wafer transfer chamber, wherein
when a value measured by the humidity sensor is greater than a preset humidity limit value, the controller operates the second exhaust part to allow the downflow in the direction opposite to the wafer storage container.

41. The EFEM system of claim 38, further comprising:
a concentration sensor measuring a concentration of noxious gas inside the wafer storage container; and
an airflow control device provided in the wafer transfer chamber and controlling a direction of the downflow in accordance with a change in angle, wherein
when a value measured by the concentration sensor is greater than a preset concentration limit value, the controller controls the angle of the airflow control device to a first direction angle such that the downflow flows in the direction of the inside of the wafer storage container.

42. The EFEM system of claim 41, further comprising:
a flow sensor measuring a flow rate of the downflow flowing in the direction of the inside of the wafer storage container;
an airflow control device heater provided at the airflow control device to increase a temperature inside the wafer transfer chamber during operation; and
a gas spraying part provided at the airflow control device to spray gas during operation, wherein
when the downflow flows in the direction of the inside of the wafer storage container by the airflow control device and a value measured by the flow sensor is less than a flow rate limit value preset in the controller, the controller operates at least one of the airflow control device heater or the gas spraying part.

43. The EFEM system of claim 38, further comprising:
a humidity sensor measuring a humidity inside the wafer storage container; and
an airflow control device provided in the wafer transfer chamber and controlling a direction of the downflow in accordance with a change in angle, wherein
when a value measured by the humidity sensor is greater than a preset humidity limit value, the controller controls the angle of the airflow control device to a second direction angle such that the downflow flows in the direction opposite to the wafer storage container.

44. The EFEM system of claim 43, further comprising:
a temperature sensor measuring a temperature inside the wafer storage container; and
a heater provided at the wafer storage container to increase a temperature inside the wafer storage container during operation, wherein
when the downflow flows in the direction opposite to the wafer storage container by the airflow control device and a value measured by the temperature sensor is less than a preset temperature limit value, the controller operates the heater.
